(19) United States
(12) Patent Application Publication
(10) Pub. No.: US 2025/0299706 A1
(43) Pub. Date: Sep. 25, 2025

(54) SEMICONDUCTOR MEMORY DEVICE

(71) Applicant: Kioxia Corporation, Tokyo (JP)

(72) Inventor: Tomohiro MATSUDA, Yokkaichi Mie (JP)

(73) Assignee: Kioxia Corporation, Tokyo (JP)

(21) Appl. No.: 19/060,866

(22) Filed: Feb. 24, 2025

(30) Foreign Application Priority Data
Mar. 21, 2024 (JP) 2024-045434

(51) Int. Cl. G11C 5/06; G11C 16/04; H10B 43/10; H10B 43/20

(52) U.S. Cl. CPC G11C 5/063; G11C 16/0483; H10B 43/10; H10B 43/20

(57) ABSTRACT

According to one embodiment, a semiconductor memory device includes a structural body including a stacked body in which conductive layers are stacked in a first direction, a plate-shaped structure extending in the first and second directions in the structural body, first and second pillar structures extending in the first direction in the stacked and structural body, respectively, and each of which a plurality of layers are stacked from an outer peripheral surface side toward an inner side. The second pillar structure does not function as a NAND string. Materials of the plurality of layers in the first and second pillar structures are respectively same. A part of a side surface of the plate-shaped structure is conformed to a part of a side surface of the second pillar structure.

### CROSS-REFERENCE TO RELATED APPLICATIONS

This application is based upon and claims the benefit of priority from Japanese Patent Application No. 2024-045434, filed Mar. 21, 2024, the entire contents of which are incorporated herein by reference.

### FIELD

Embodiments described herein relate generally to a semiconductor memory device.

### BACKGROUND

In three-dimensional NAND-type nonvolatile semiconductor memory devices in which a plurality of memory cells are stacked on a semiconductor substrate, it is desired that the degree of integration be increased.

### BRIEF DESCRIPTION OF THE DRAWINGS

FIG. 1 is a diagram schematically showing an overall configuration of a semiconductor memory device according to a first embodiment.

FIG. 2 is a cross-sectional view schematically showing a part of a configuration of a memory region of the semiconductor memory device according to the first embodiment.

FIG. 3 is a planar pattern diagram schematically showing a part of the configuration of the memory region of the semiconductor memory device according to the first embodiment.

FIG. 4 is a cross-sectional view schematically showing a detailed configuration of a memory cell portion of the semiconductor memory device according to the first embodiment.

FIG. 5 is a cross-sectional view schematically showing a detailed configuration of the memory cell portion of the semiconductor memory device according to the first embodiment.

FIGS. 6A and 6B are each a cross-sectional view schematically showing a part of a configuration of a stairs region of the semiconductor memory device according to the first embodiment.

FIG. 7 is a planar pattern diagram schematically showing a part of a configuration of the stairs region of the semiconductor memory device according to the first embodiment.

FIG. 8 is a cross-sectional view schematically showing a detailed configuration of a pillar structure and the like in a flat portion of a stacked body of the semiconductor memory device according to the first embodiment.

FIG. 9 is a cross-sectional view schematically showing a detailed configuration of the pillar structure and the like in the flat portion of the stacked body of the semiconductor memory device according to the first embodiment.

FIGS. 10A, 10B, 10C, 10D, 10E, 10F, 10G and 10H are each a cross-sectional view schematically showing a part of a method of manufacturing the semiconductor memory device according to the first embodiment.

FIG. 11 is a cross-sectional view schematically showing a part of a configuration of a memory region of a semiconductor memory device according to a second embodiment.

FIG. 12 a cross-sectional view schematically showing a part of a configuration of a stairs region of the semiconductor memory device according to the second embodiment.

FIGS. 13A, 13B, 13C, 13D, 13E, 13F, 13G, 13H, 13I, 13J, 13K, 13L, 13M and 13N are each a cross-sectional view schematically showing a part of a method of manufacturing the semiconductor memory device according to the second embodiment.

FIG. 14 is a cross-sectional view schematically showing a part of a configuration of a memory region of a semiconductor memory device according to a third embodiment.

FIG. 15 a cross-sectional view schematically showing a part of a configuration of a stairs region of the semiconductor memory device according to the third embodiment.

FIG. 16 a planar pattern diagram schematically showing a part of a configuration of the stairs region of the semiconductor memory device according to the third embodiment.

FIG. 17 is a cross-sectional view schematically showing a detailed configuration of a pillar structure and the like in a flat portion of a stacked body of the semiconductor memory device according to the third embodiment.

FIG. 18 is a cross-sectional view schematically showing a detailed configuration of the pillar structure and the like in the flat portion of the stacked body of the semiconductor memory device according to the third embodiment.

FIGS. 19A, 19B, 19C, 19D, 19E, 19F, 19G, 19H, 19I, 19J, 19K and 19L are each a cross-sectional view schematically showing a part of a method of manufacturing the semiconductor memory device according to the third embodiment.

### DETAILED DESCRIPTION

In general, according to one embodiment, a semiconductor memory device includes: a structural body including a stacked body in which a plurality of conductive layers are stacked to be apart from each other in a first direction; a plate-shaped structure extending in the first direction and a second direction that intersects the first direction in the structural body to at least a height level corresponding to a height level of a lower surface of the stacked body; a first pillar structure extending in the first direction in the stacked body and functioning as a NAND string, the first pillar structure having a structure in which a plurality of layers including a first semiconductor layer and extending in the first direction are stacked from an outer peripheral surface side toward an inner side; and a second pillar structure extending in the first direction in the structural body and not functioning as a NAND string, the second pillar structure having a structure in which a plurality of layers including a second semiconductor layer and extending in the first direction are stacked from an outer peripheral surface side toward an inner side, wherein materials of the plurality of layers stacked from the outer peripheral surface side toward the inner side in the second pillar structure are respectively same as materials of the plurality of layers stacked from the outer peripheral surface side toward the inner side in the first pillar structure, and a part of a side surface of the plate-shaped structure is conformed to a part of a side surface of the second pillar structure and includes a recess portion based on the part of the side surface of the second pillar structure.

Embodiments will be described hereinafter with reference to the accompanying drawings.

### First Embodiment

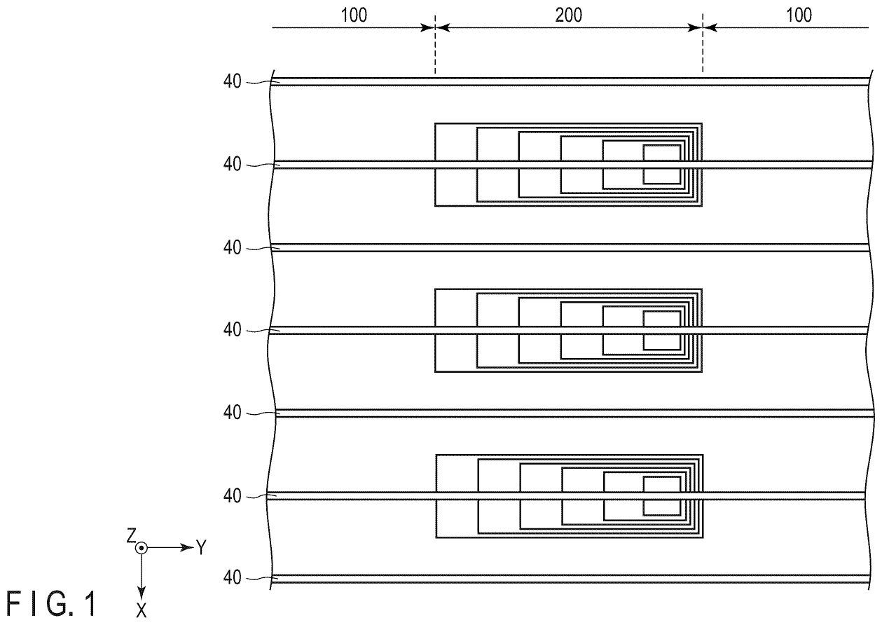

FIG. 1 is a diagram schematically showing an overall configuration of a semiconductor memory device (NAND-type nonvolatile semiconductor memory device) according to the first embodiment.

The semiconductor memory device of this embodiment includes a memory region 100 and a stairs region 200 arranged in a Y direction. The memory region 100 and the stairs region 200 are provided with a stacked body and the like, which will be described later.

The memory region 100 is partitioned into a plurality of blocks in the X direction by a plurality of plate-shaped structures 40 each extending in the Y direction and the Z direction in the stacked body. As will be described later, each block is provided with a plurality of pillar structures each extending in the Z direction in the stacked body.

The stairs region 200 includes a portion of the stacked body, which is processed into a stair-like shape. In the stairs region 200 shown in FIG. 1, three regions processed into a stair-like shape are arranged in the X direction. Each of the three regions processed into a stair-like shape includes a stairs portion processed into a stair-like shape in the X direction and a stairs portion processed into a stair-like shape in the Y direction. In the three regions processed into a stair-like shape, stairs processed into a valley-like shape from the outside toward inside are provided. That is, in the three regions, the height of the stacked body is lower on the inside than on the outside.

Further, in the stairs region 200 as well, a plurality of plate-shaped structures 40 extend from the memory region 100, and each of the three regions described above is divided into two parts in the X direction by the plate-shaped structure 40 extending in the Y direction. As will be described later, the stairs region 200 is provided with a plurality of pillar structures each extending in the Z direction.

Note that the X direction, Y direction and Z direction are directions intersecting each other. More specifically, the X directions, Y directions and Z direction are orthogonal to each other.

Further, in the following descriptions, the case where the stairs are simply ascending or descending is described, but it is also possible to use stairs in which ascending parts and descending parts are mixed.

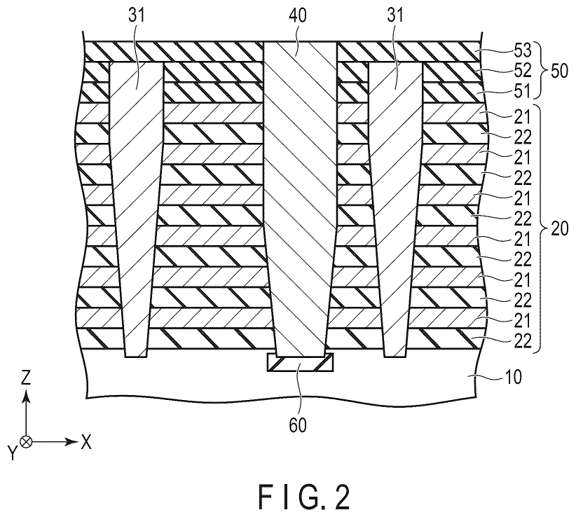

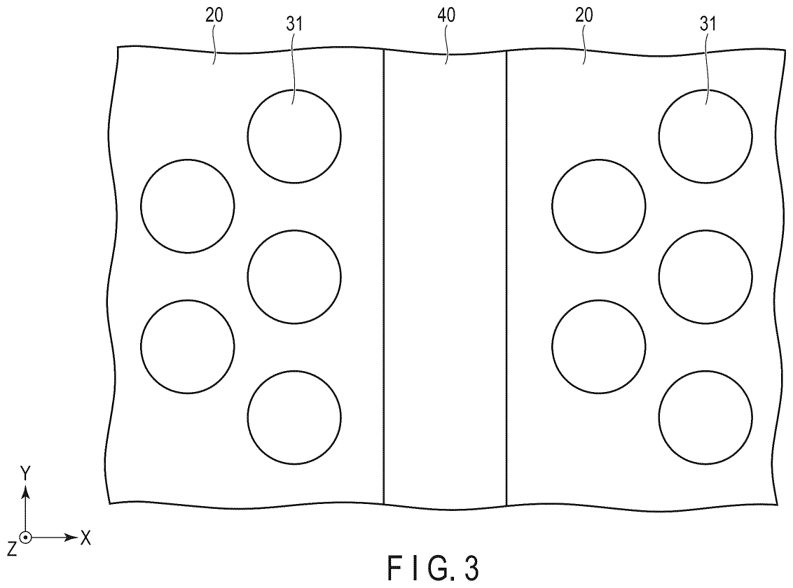

FIG. 2 is a cross-sectional view schematically showing a part of the configuration of the memory region 100. FIG. 3 is a planar pattern diagram schematically showing a part of the configuration of the memory region 100.

In the memory region 100, a stacked body 20, a plurality of pillar structures 31, and a plurality of plate-shaped structures 40 and the like are provided on a lower region 10 that includes a semiconductor and the like, that function as at least a part of a source line for the NAND string.

The stacked body 20 includes a plurality of conductive layers 21 stacked to be apart from each other in the Z direction. More specifically, the stacked body 20 includes a plurality of conductive layers 21 and a plurality of insulating layers 22 that are stacked in the Z direction in an alternating manner.

Each of the conductive layers 21 functions as a word line or select gate line for the NAND string. Each of the insulating layers 22 has the function of insulating adjacent conductive layers 21 from each other. The conductive layers 21 are each formed of a metal material such as of tungsten, and the insulating layers 22 are each formed of an insulating material such as silicon oxide.

Of the plurality of conductive layers 21, one or more of the conductive layers on a lower layer side, including the lowermost conductive layer 21, function as source-side select gate lines, and one or more of the conductive layers 21 on an upper layer side, including the uppermost conductive layer 21, function as drain-side select gate lines. Those of the conductive layers 21 which are provided between the source-side select gate lines and the drain-side select gate lines function as word lines.

Each of the pillar structures 31 extends in the Z direction in the stacked body 20 to reach the lower region 10 and functions as a main part of the NAND string. The pillar structures 31 each include a semiconductor layer connected to a semiconductor in the lower region 10 that functions as a source line, and has a structure in which a plurality of layers that extend in the Z direction are stacked from an outer peripheral surface side of the pillar structure 31 toward an inner side. Further, the entire pillar structure 31 is apart from the adjacent plate-shaped structure 40. More specifically, the pillar structure 31 and the adjacent plate-shaped structure 40 are apart from each other by the plurality of conductive layers 21 and the plurality of insulating layers 22. Further, when viewed in the Z direction, the pattern of the pillar structure 31 has a circular or elliptical planar shape.

The pillar structure 31 is surrounded by the plurality of conductive layers 21 and the plurality of insulating layers 22, and the NAND string is formed by the pillar structure 31 and the plurality of conductive layers 21 surrounding the pillar structure 31. More specifically, a memory cell is formed by a conductive layer 21 that functions as a word line and a part of the pillar structure 31 surrounded by the conductive layer 21 that functions as the word line. Further, a select transistor is formed by the conductive layer 21 that functions as a select gate line and a part of the pillar structure 31 surrounded by the conductive layer 21 that functions as the select gate line.

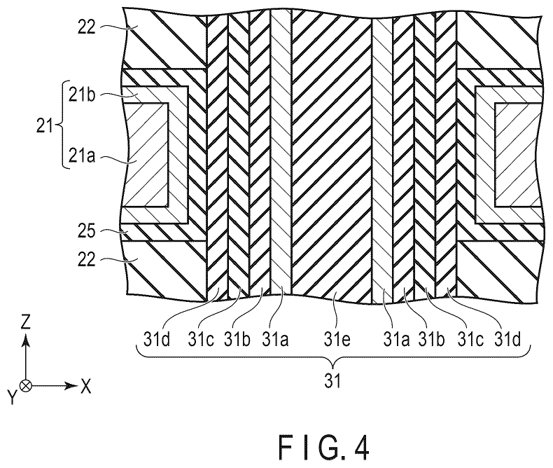

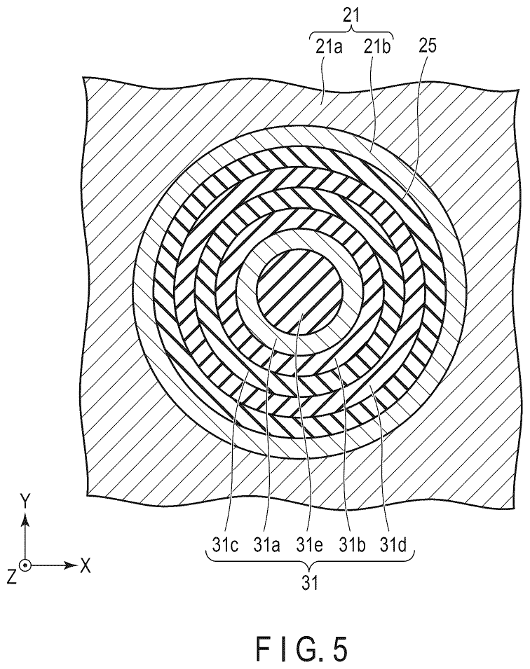

FIGS. 4 and 5 are each a cross-sectional view schematically showing a detailed configuration of the memory cell portion formed by the conductive layer 21 and the pillar structure 31. FIG. 4 is a cross-sectional view parallel to the Z direction, and FIG. 5 is a cross-sectional view perpendicular to the Z direction.

The pillar structure 31 includes a semiconductor layer 31a, a tunnel insulating layer 31b, a charge storage layer 31c, a block insulating layer 31d, and a core insulating layer 31e, and these layers 31a to 31e extend in the Z direction. Further, the pillar structure 31 has a structure in which the block insulating layer 31d, charge storage layer 31c, tunnel insulating layer 31b, semiconductor layer 31a, and core insulating layer 31e are stacked in this order from the outer peripheral surface side of the pillar structure 31 toward the inner side.

The semiconductor layer 31a, tunnel insulating layer 31b, charge storage layer 31c, and block insulating layer 31d, each have a cylindrical shape, and the core insulating layer 31e has a columnar shape. More specifically, the semiconductor layer 31a surrounds a side surface of the core insulating layer 31e, the tunnel insulating layer 31b surrounds a side surface of the semiconductor layer 31a, the charge storage layer 31c surrounds a side surface of the tunnel insulating layer 31b, and the block insulating layer 31d surrounds a side surface of the charge storage layer 31c.

For example, the semiconductor layer 31a is formed of silicon, the tunnel insulating layer 31b is formed of silicon oxide, the charge storage layer 31c is formed of silicon nitride, the block insulating layer 31d is formed of silicon oxide, and the core insulating layer 31e is formed of silicon oxide.

The conductive layer 21 includes a metal layer 21a formed of a metal material such as tungsten or molybdenum, and a barrier metal layer 21b formed of a material such as titanium nitride. On an outer side of the conductive layer 21, a metal oxide layer 25 formed of a material such as aluminum oxide is provided.

Returning to the explanation of FIGS. 2 and 3, each plate-shaped structure 40 extends in the Y direction and Z direction in the stacked body 20 to a height level corresponding to at least a height level of the lower surface of the stacked body 20. More specifically, each plate-shaped structure 40 extends in the Z direction to the insulating portion 60 provided in the surface area of the lower region 10 while penetrating the lowermost conductive layer 21 and the lowermost insulating layer 22. As shown in FIG. 1, the plurality of plate-shaped structures 40 are arranged in the X direction, and the plurality of pillar structures 31 are partitioned into a plurality of blocks in the X direction by the plate-shaped structures 40. The plate-shaped structures 40 are formed by filling the slits (trenches) used in the replacement process described below with a predetermined material (for example, tungsten).

An insulating portion 50 including insulating layers 51, 52, and 53 is provided on the stacked body 20 and on the pillar structures 31. These insulating layers 51, 52 and 53 are formed of silicon oxide or the like.

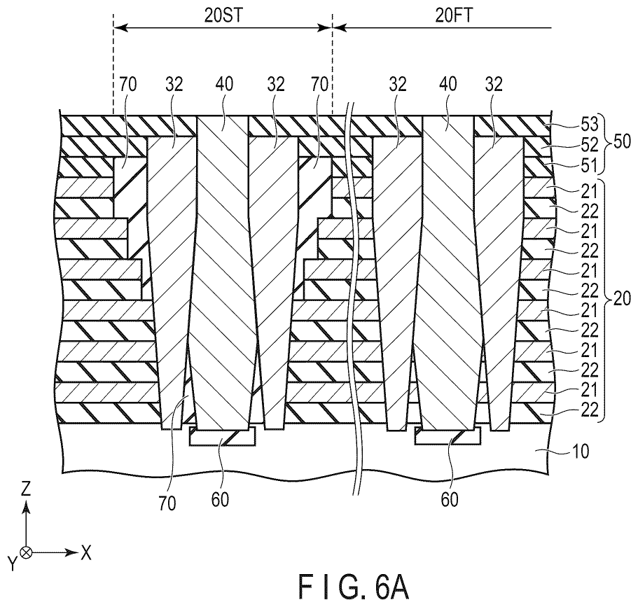

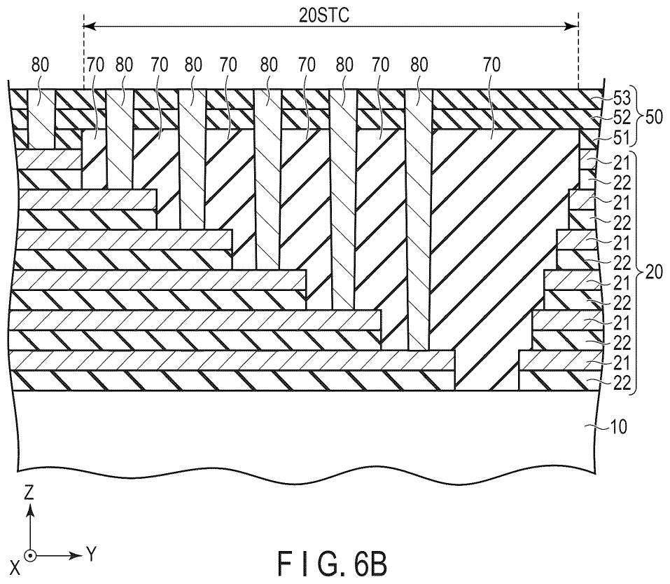

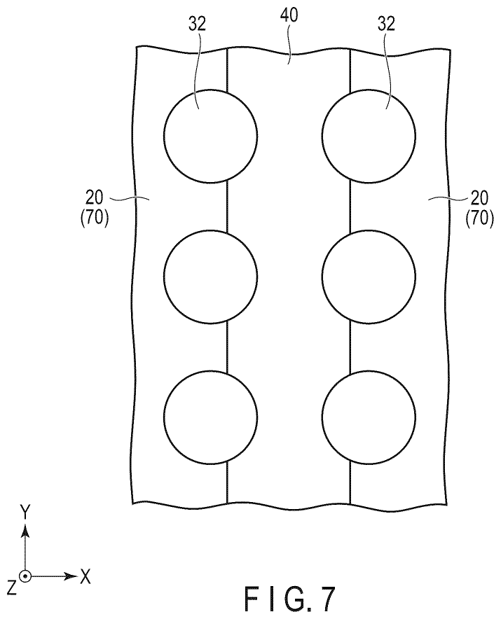

FIGS. 6A and 6B are each a cross-sectional view schematically showing a part of the configuration of the stairs region 200. FIG. 6A is a cross-sectional view taken along the X direction, and FIG. 6B is a cross-sectional view taken along the Y direction. FIG. 7 is a planar pattern diagram schematically showing a part of the configuration of the stairs region 200.

In the stairs region 200, a stacked body 20, a plurality of pillar structures 32, a plurality of plate-shaped structures 40, an insulating layer 70, contacts 80 and the like are provided on the lower region 10.

The stacked body 20 is provided continuously from the memory region 100 and, as already described, includes a plurality of conductive layers 21 and a plurality of insulating layers 22 that are stacked alternately in the Z direction. However, as already mentioned, the stacked body 20 of the stairs region 200 includes a part that is processed in a stair-like manner along the X direction and a part that is processed in a stair-like manner along the Y direction. FIGS. 6A and 7 show the region that includes the stairs portion 20ST processed in a stair-like manner along the X direction. FIG. 6B shows the region including a stairs portion 20STC processed in a stair-like manner along the Y direction. Further, the stacked body 20 of the stairs region 200 also includes a flat portion 20FT, which extends flatly in the X direction from the uppermost surface of the stairs portion 20ST of the stacked body 20.

Each pillar structure 32 extends in the Z direction through the structural body including the stacked body 20 and the insulating layer 70 to reach the lower region 10. More specifically, the stairs region 200 is provided with pillar structures 32 that extend in the flat portion 20FT of the stacked body 20 in the Z direction (the two pillar structures 32 shown on the right side in FIG. 6A) and pillar structures 32 that extend in the stairs portion 20ST of the stacked body 20 in the Z direction (the two pillar structures 32 shown on the left side in FIG. 6A). The pillar structures 32 that extend in the stairs portion 20ST in the Z direction also includes a portion that extends in the Z direction in the insulating layer 70 that covers an end portion of the stairs portion 20ST.

The relationship between the pattern of the pillar structure 32 and the pattern of the plate-shaped structure 40 in the flat portion 20FT is substantially same as the relationship between the pattern of the pillar structure 32 and the pattern of the plate-shaped structure 40 in the stairs portion 20ST. For this reason, FIG. 7 shows the pattern of the flat portion 20FT and the pattern of the stairs portion 20ST in a common diagram.

Each of the pillar structures 32 in the stairs region 200 is provided to support a preliminary stacked body in the replacement process, which will be described later, and does not function as a NAND string.

Further, the pillar structure 32 is different from the pillar structure 31 provided in the memory region 100 and it includes a portion that is not substantially apart from a plate-shaped structure 40 adjacent thereto. That is, in the stairs region 200, a part of a side surface of the plate-shaped structure 40 is conformed to a part of a side surface of the pillar structure 32, and includes a recess portion based on the part of the side surface of the pillar structure 32 (a recess portion based on the shape of the part of the side surface of the pillar structure 32).

Specifically, a part of the side surface along the Y direction and Z direction of the plate-shaped structure 40 is conformed to a part of the side surface of the pillar structure 32 and includes a recess portion based on the part of the side surface of the pillar structure 32. From another perspective, as shown in FIG. 7, the pattern of the plate-shaped structure 40 includes a recess portion based on the pattern of the pillar structure 32 as viewed in the Z direction. Note that in the example of FIG. 7, the pattern of the pillar structure 32 has a circular planar shape as viewed in the Z direction, but it may as well have an elliptical planar shape.

Further, the pillar structure 32 has a structure in which a plurality of layers that include a semiconductor layer and extend in the Z direction are stacked from the outer peripheral surface side of the pillar structure 32 toward the inner side.

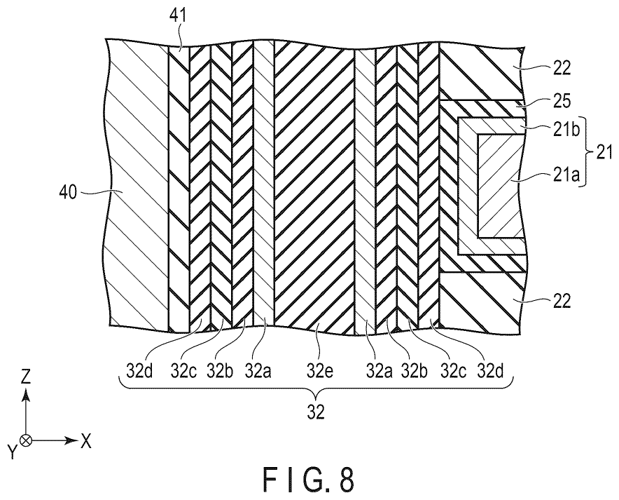

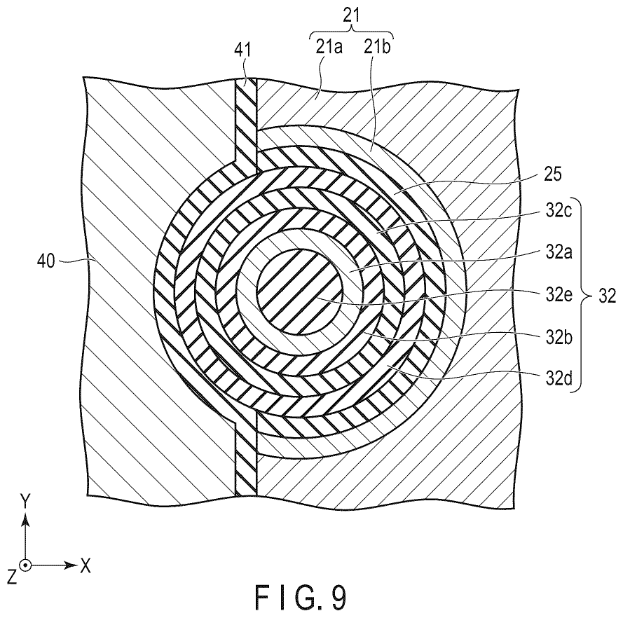

FIGS. 8 and 9 are cross-sectional views schematically showing a detailed configuration of the pillar structure 32 and the like in the flat portion 20FT of the stacked body 20. FIG. 8 is a cross-sectional view parallel to the Z direction, and FIG. 9 is a cross-sectional view perpendicular to the Z direction. The basic structure of the pillar structure 32 in the stairs portion 20ST of the stacked body 20 as well is substantially same as the structure of the pillar structure 32 shown in FIGS. 8 and 9.

The pillar structure 32 includes a semiconductor layer 32a, a tunnel insulating layer 32b, a charge storage layer 32c, a block insulating layer 32d, and a core insulating layer 32e, and these layers 32a to 32e extend in the Z direction. Further, the pillar structure 32 has a structure in which the block insulating layer 32d, charge storage layer 32c, tunnel insulating layer 32b, semiconductor layer 32a, and core insulating layer 32e are stacked in the order from the outer peripheral surface side of the pillar structure 32 toward the inner side.

The semiconductor layer 32a, tunnel insulating layer 32b, charge storage layer 32c, and block insulating layer 32d each have a cylindrical shape, and the core insulating layer 32e has a columnar shape. Specifically, the semiconductor layer 32a surrounds the side surface of the core insulating layer 32e, the tunnel insulating layer 32b surrounds the side surface of the semiconductor layer 32a, the charge storage layer 32c surrounds the side surface of the tunnel insulating layer 32b, and the block insulating layer 32d surrounds the side surface of the charge storage layer 32c.

In addition, the materials of the layers 32a, 32b, 32c, 32d, and 32e of the pillar structure 32 are respectively same as the materials of the layers 31a, 31b, 31c, 31d, and 31e of the pillar structure 31. That is, the semiconductor layer 32a, the tunnel insulating layer 32b, the charge storage layer 32c, the block insulating layer 32d, and the core insulating layer 32e are respectively formed from the same material as those of the semiconductor layer 31a, the tunnel insulating layer 31b, the charge storage layer 31c, the block insulating layer 31d, and the core insulating layer 31e.

Further, on the side surface of the plate-shaped structure 40, a sidewall insulating layer 41 formed of silicon oxide is provided.

As described above, the basic configuration of the pillar structure 32 is same as the basic configuration of the pillar structure 31. The thickness of each layer of the pillar structure 31 and the thickness of the corresponding layer of the pillar structure 32 may be the same as or different from each other.

Returning to the explanations of FIGS. 6A, 6B and 7, each of the plate-shaped structures 40 extends in the structural body including the stacked body 20 and the insulating layer 70 to at least the height level corresponding to the height level of the lower surface of the stacked body 20 in the Y direction and the Z direction.

Specifically, in the flat portion 20FT of the stacked body 20, each plate-shaped structure 40 extends in the stacked body 20 in the Y direction and the Z direction to at least the height level corresponding to the height level of the lower surface of the stacked body 20, as in the case of the memory region 100. More specifically, each plate-shaped structure 40 extends in the Z direction to reach the insulating portion 60 provided in the surface area of the lower region 10 while penetrating the lowermost conductive layer 21 and the lowermost insulating layer 22.

In the stairs portion 20ST of the stacked body 20, each plate-shaped structure 40 extends in the insulating layer 70 or the structural body including the stacked body 20 and the insulating layer 70 to at least the height level corresponding to the height level of the lower surface of the stacked body 20 in the Y direction and the Z direction. More specifically, each plate-shaped structure 40 extends in the Z direction to reach the insulating portion 60 provided in the surface area of the lower region 10 while penetrating the part processed in a stair-like manner along the Y direction of the stacked body 20 and the insulating layer 70 covering this part.

As shown in FIG. 6B, in the stairs portion 20STC, each of a plurality of contacts 80 is connected to a respective conductive layer 21 of the plurality of conductive layers 21. Through these contacts 80 and conductive layers 21, control signals are supplied to the NAND string.

Further, as shown in FIGS. 6A and 6B, an insulating portion 50 including insulating layers 51, 52, and 53 is provided on the stacked body 20 and on the pillar structures 32 as in the case shown in FIG. 2.

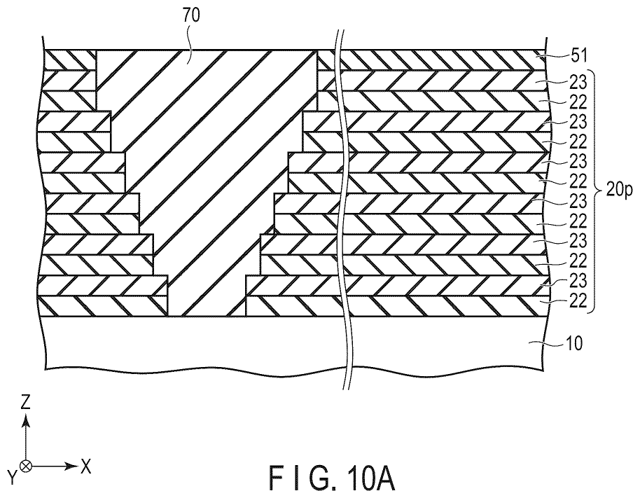

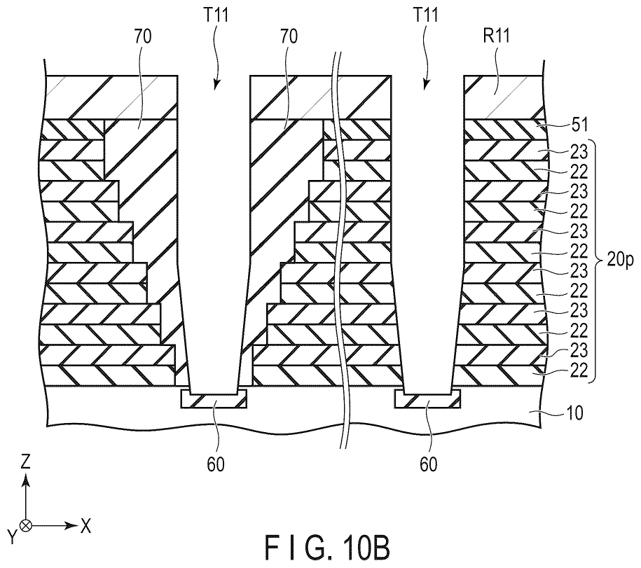

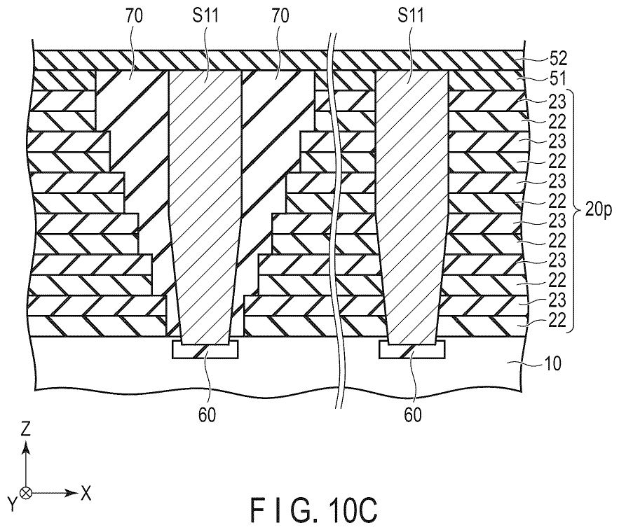

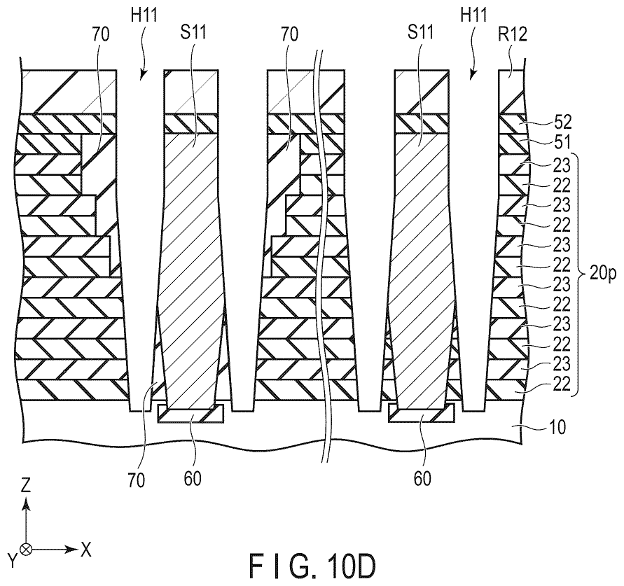

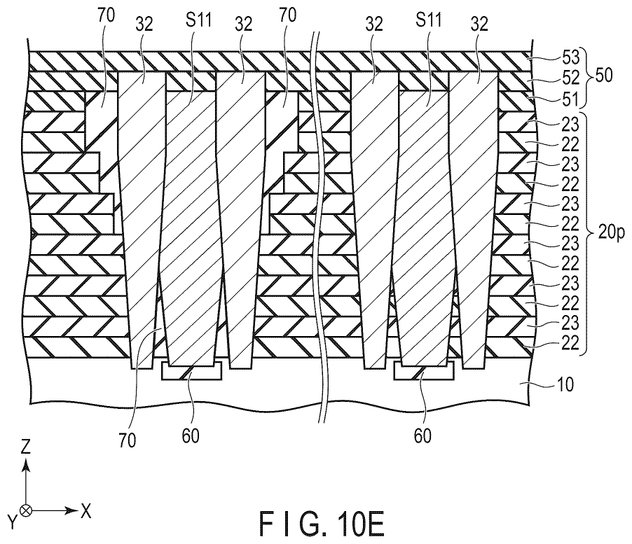

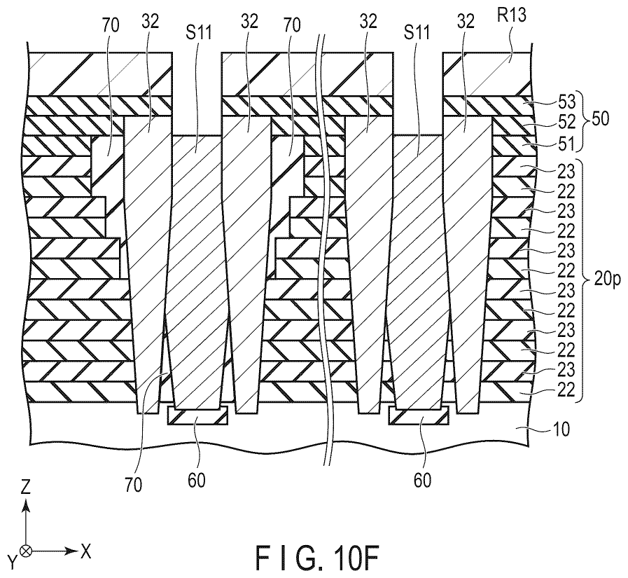

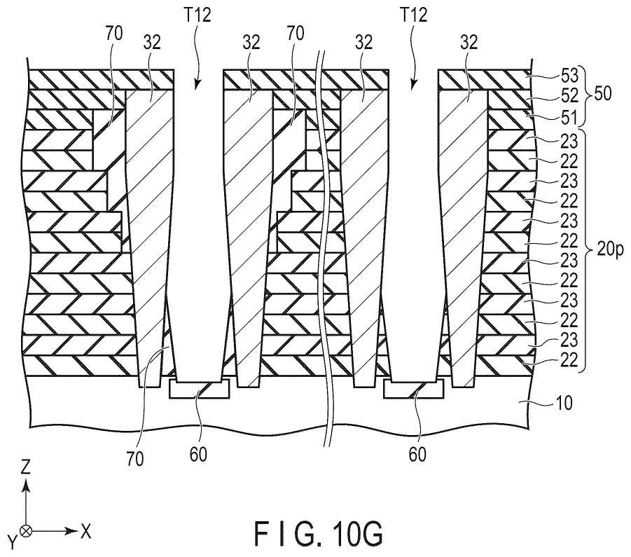

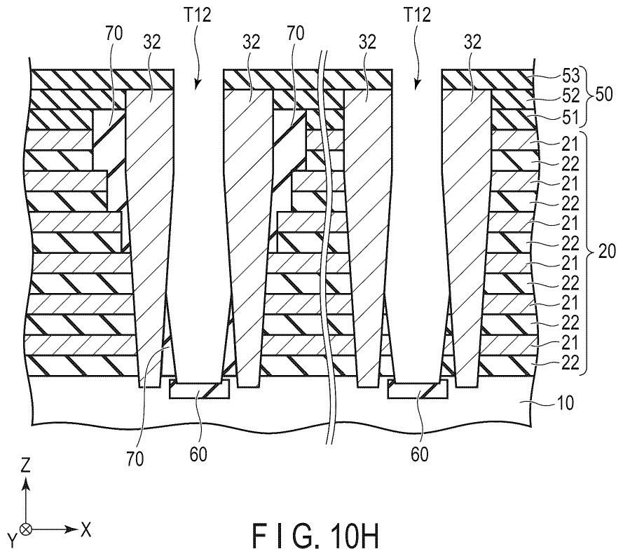

Next, a method of manufacturing the semiconductor memory device of this embodiment will be explained with reference to FIGS. 10A to 10H. Note here that FIGS. 10A to 10H show the formation process of the stairs region 200 in a schematic manner, a common formation process is performed for the memory region 100 as well.

First, as shown in FIG. 10A, a structure including a preliminary stacked body 20p, an insulating layer 51 and an insulating layer 70 is formed on the lower region 10. The preliminary stacked body 20p has a structure in which a plurality of insulating layers 22 and a plurality of sacrificial layers 23 are stacked alternately in the Z direction. The insulating layers 22 are formed of silicon oxide, and the sacrificial layers 23 are formed of silicon nitride. The insulating layer 70 is formed to cover the stair-like end portions of the preliminary stacked body 20p, which face each other. In this processing step, the preliminary stacked body 20p and the like are formed similarly in the memory region 100 as well.

Next, as shown in FIG. 10B, the preliminary stacked body 20p, insulating layer 51 and insulating layer 70 are etched by reactive ion etching (RIE) using a resist pattern R11 as a mask, thus forming a trench T11 that extends in the Y direction. At this time, the surface area of the lower region 10 is etched as well, and the location of the bottom surface of the trench T11 is lower than the location of the upper surface of the lower region 10. Further, an insulating portion 60 is formed near the bottom surface of the trench T11. In this processing step, a trench similar to the trench 11 or the like is formed in the memory region 100 as well.

Next, as shown in FIG. 10C, after removing the resist pattern R11, a sacrificial layer S11 is formed on the structure obtained in the processing step shown in FIG. 10B. For the sacrificial layer S11, amorphous silicon is used. Subsequently, by etching back the sacrificial layer S11, a structure in which the trench T11 is filled with the sacrificial layer S11 is obtained. Further, an insulating layer 52 is formed on the structure thus obtained. In this processing step, a sacrificial layer similar to the sacrificial layer S11 or the like is formed in the memory region 100 as well.

Next, as shown in FIG. 10D, using the resist pattern R12 as a mask, the preliminary stacked body 20p, insulating layers 51, 52 and 70 are etched by RIE to form a hole H11. In this etching process, part of the sacrificial layer S11 is etched as well, and the shape of the sacrificial layer S11 is changed. Further, the surface area of the lower region 10 is etched as well, and the location of the bottom surface of the hole H11 is lower than the upper surface of the lower region 10. In this processing step, a hole similar to the hole H11 or the like is formed in the memory region 100 as well. However, in the memory region 100, the sacrificial layer corresponding to the sacrificial layer S11 is not etched.

Next, as shown in FIG. 10E, after removing the resist pattern R12, a pillar structure 32 is formed in the hole H11. Here, since a part of the side surface of the sacrificial layer S11 is exposed by the etching process of FIG. 10D, a part of the side surface of the pillar structure 32 and a part of the side surface of the sacrificial layer S11 are conformed to each other. Further, an insulating layer 53 is formed on the structure thus obtained. In this processing step, a pillar structure 31 is formed similarly in the memory region 100 as well. However, in the memory region 100, the pillar structure 31 and the sacrificial layer S11 are apart from each other.

Next, as shown in FIG. 10F, the insulating layer 52 and the insulating layer 53 are etched using the resist pattern R13 as a mask, and the upper surface of the sacrificial layer S11 is exposed.

Next, as shown in FIG. 10G, after the resist pattern R13 is removed, the sacrificial layer S11 is removed by wet etching to form a trench T12. In this way, a part of the side surface of the pillar structure 32 is exposed. In this processing step, a trench similar to the trench T12 is formed in the memory region 100 as well. However, in the memory region 100, the side surface of the pillar structure 31 is not exposed.

Next, as shown in FIG. 10H, the plurality of sacrificial layers 23 are etched via the trench T12 to form a plurality of spaces. Further, the plurality of spaces are filled with the plurality of conductive layers 21 such as tungsten layers. Thus, the replacement process, in which the sacrificial layers 23 are replaced by the conductive layers 21, is completed. As a result, a stacked body 20 is formed, in which a plurality of conductive layers 21 and a plurality of insulating layers 22 are stacked alternately. In this processing step, the replacement process is performed similarly in the memory region 100 as well, and thus the stacked body 20 is formed.

After that, the trench T12 is filled with a metal material such as tungsten, and thus a plate-shaped structure 40 is formed, and the structure shown in FIGS. 6A and 7 is obtained. Further, in the memory region 100, the structure shown in FIGS. 2 and 3 is obtained. Furthermore, the contacts 80 are formed, and thus the structure shown in FIG. 6B is obtained.

As described above, in this embodiment, the pillar structure 32, which is provided in the stairs region 200 and does not function as a NAND string, includes a part that is not substantially apart from the plate-shaped structure 40 adjacent thereto. That is, a part of the side surface of the plate-shaped structure 40 is conformed to a part of the side surface of the pillar structure 32 and includes a recess portion based on the part of the side surface of the pillar structure 32. With this configuration, the pillar structure 32 can be provided adjacent to the plate-shaped structure 40, and thus it is possible to enhance the degree of integration of the semiconductor memory device. Further, in the pillar structure 32 provided adjacent to the plate-shaped structure 40, the function of supporting the preliminary stacked body 20p in which a plurality of spaces are formed is enhanced during the replacement process.

In this embodiment, the basic configuration of the pillar structure 32 provided in the stairs region 200 is same as the basic configuration of the pillar structure 31 provided in the memory region 100 and functioning as a NAND string. With this configuration, it is possible to form the pillar structure 32 in a common process to that of the pillar structure 31.

Further, in this embodiment, a sacrificial layer S11 is formed in advance in the region where the plate-shaped structure 40 is to be formed, the pillar structure 32 is formed in a state where the sacrificial layer S11 is formed, and the plate-shaped structure 40 is formed in the trench T12 obtained by removing the sacrificial layer S11 after that. Therefore, as will be described below, it is possible to accurately form the structure described above.

If, without forming the sacrificial layer S11, a pillar structure 32 having the same basic configuration as that of the pillar structure 31 is formed, and then the plate-shaped structure 40 is formed so as not to be substantially apart from the pillar structure 32, there is a risk that a part of the pillar structure 32 will be damaged by RIE when forming the trench for forming the plate-shaped structure 40. As a result, a precise pillar structure 32 cannot be obtained undesirably. Here, it is also possible to consider the forming of the pillar structure 32 using silicon oxide or the like, but in this case, the pillar structure 32 may shrink due to thermal treatment or the like, and there is a risk that the upper surface of the structural body, which includes the stacked body 20 and the insulating layer 70, in the stairs region 200 may sink with respect to the upper surface of the stacked body 20 in the memory region 100.

In this embodiment, the plate-shaped structure 40 can be formed without causing a damage to the pillar structure 32 by using the method described above. That is, the sacrificial layer S11 can be easily removed by wet etching or the like, and therefore it is possible to form the trench T12 without causing a damage to the pillar structure 32. Therefore, the pillar structure 32 and the plate-shaped structure 40 can be accurately formed. Further, by forming the pillar structure 32, which includes the semiconductor layer 32a that is not easily shrunk by thermal treatment and the like, it is possible to suppress the sinking of the structural body including the stacked body 20 and the insulating layer 70 in the stairs region 200.

### Second Embodiment

Next, a semiconductor memory device (NAND-type nonvolatile semiconductor memory device) according to the second embodiment will be explained. Note that the basic items are similar to those of the first embodiment, and the explanation of the items already described in the first embodiment is omitted.

The overall configuration of the semiconductor memory device in this embodiment is similar to that shown in FIG. 1, and the explanation thereof is omitted here.

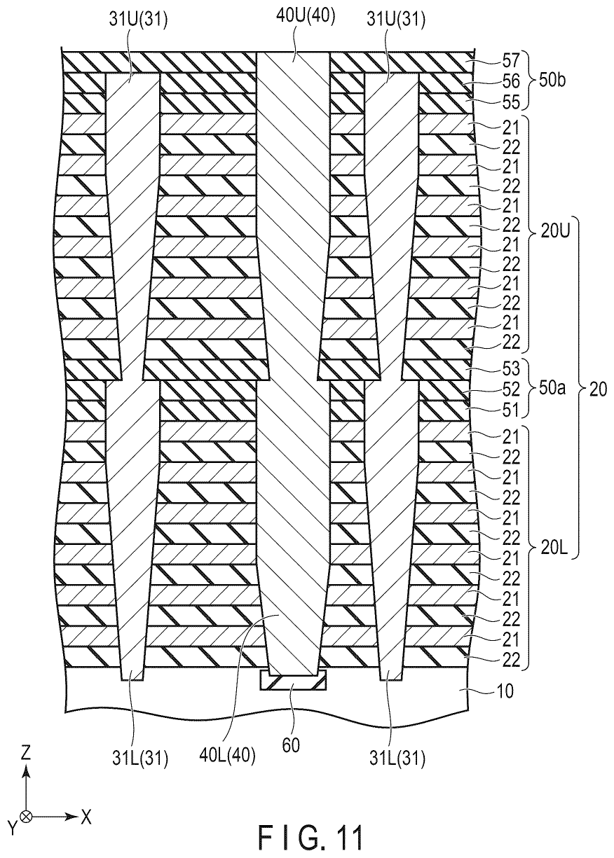

FIG. 11 is a schematic cross-sectional view showing a part of a configuration of the memory region 100. The schematic planar pattern of the part of the configuration of the memory region 100 is similar to that shown in FIG. 3 of the first embodiment, and therefore the illustration by a figure is omitted.

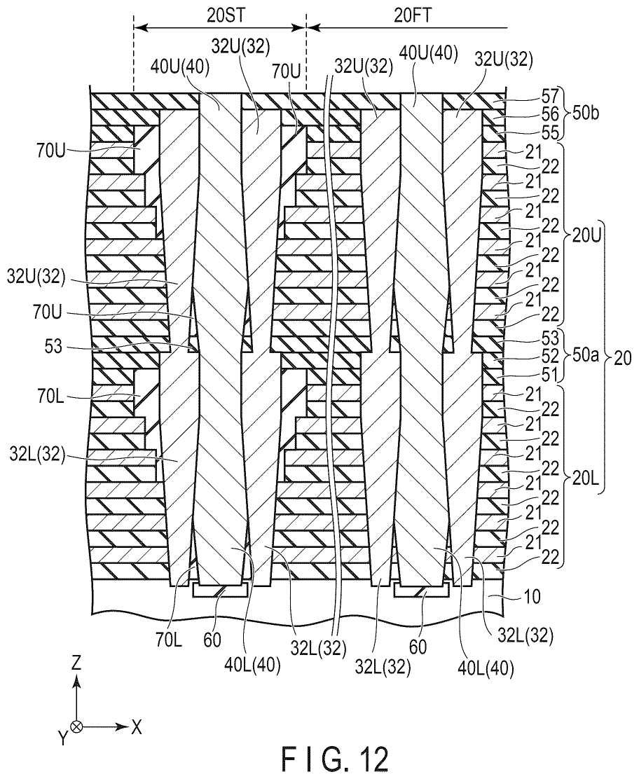

FIG. 12 is a schematic cross-sectional view showing a part of a configuration of the stairs region 200. The schematic planar pattern of the part of the configuration of the stairs region 200 is similar to that shown in FIG. 7 of the first embodiment, and therefore the illustration by a figure is omitted here.

As shown in FIGS. 11 and 12, in this embodiment, the stacked body 20 includes a stacked portion 20L and a stacked portion 20U provided on an upper layer side of the stacked portion 20L. Further, the plate-shaped structure 40 includes a plate-shaped structure portion 40L and a plate-shaped structure portion 40U provided on an upper layer side of the plate-shaped structure portion 40L.

In the memory region 100, the pillar structure 31 includes a pillar structure portion 31L and a pillar structure portion 31U provided on an upper layer side of the pillar structure portion 31L. Further, in the stairs region 200, the pillar structure 32 includes a pillar structure portion 32L and a pillar structure portion 32U provided on an upper layer side of the pillar structure portion 32L.

The basic structure and basic functions of each of the stacked body 20, pillar structure 31, pillar structure 32 and plate-shaped structure 40 are similar to those of the first embodiment.

In the stairs region 200, a flat portion 20FT and a stairs portion 20ST are provided in each of the stacked portion 20L and the stacked portion 20U. The end portion of the stairs portion 20ST of the stacked portion 20L is covered by an insulating layer 70L, and the end portion of the stairs portion 20ST of the stacked portion 20U is covered by an insulating layer 70U.

Between the stacked portion 20L and the stacked portion 20U, an intermediate insulating portion 50a is provided, and the stacked portion 20L and the stacked portion 20U are apart from each other by the intermediate insulating portion 50a. The intermediate insulating portion 50a includes insulating layers 51, 52, and 53. The thickness of the intermediate insulating portion 50a is greater than the thickness of the conductive layer 21 and the thickness of the insulating layer 22. Further, the upper insulating portion 50b is provided on the stacked portion 20U, the pillar structure portion 31U, and the pillar structure portion 32U. The upper insulating portion 50b includes insulating layers 55, 56, and 57. These insulating layers 51, 52, 53, 55, 56 and 57 are formed of silicon oxide or the like.

The relationship between the stacked portion 20L, pillar structure portion 31L and plate-shaped structure portion 40L, and the relationship between the stacked portion 200, pillar structure portion 31U and plate-shaped structure portion 40U, are both similar to the relationship between the stacked body 20, pillar structure 31 and plate-shaped structure 40 described in the first embodiment. Therefore, the configuration of the pillar structure portion 31L and the like and the configuration of the pillar structure portion 31U and the like in the memory region 100 are both similar to the configuration of the pillar structure 31 and the like in the first embodiment shown in FIGS. 4 and 5.

The relationship between the stacked portion 20L, pillar structure portion 32L, plate-shaped structure portion 40L and insulating layer 70L, and the relationship between the stacked portion 20U, pillar structure portion 32U, plate-shaped structure portion 40U and insulating layer 70U are both similar to the relationship between the stacked body 20, pillar structure 32, plate-shaped structure 40 and insulating layer 70 of the first embodiment. Therefore, the configuration of the pillar structure portion 32L and the like and the configuration of the pillar structure portion 32U and the like in the stairs region 200 are both similar to the configuration of the pillar structure 32 and the like in the first embodiment shown in FIGS. 8 and 9.

That is, the plate-shaped structure portion 40L includes a recess portion based on the pillar structure portion 32L, and the plate-shaped structure portion 40U includes a recess portion based on the pillar structure portion 32U. The recess portion of the plate-shaped structure portion 40L is included at least in a region corresponding to a range between a height level corresponding to a height level of the upper surface of the stacked portion 20L and a height level corresponding to a height level of the lower surface of the stacked portion 20L. The recess portion of the plate-shaped structure portion 40U is included at least in a region corresponding to a range between a height level corresponding to a height level of the upper surface of the stacked portion 20U and a height level corresponding to a height level of the lower surface of the stacked portion 20U.

Note that though not particularly shown in the figure, in this embodiment as well, stairs portion 20STC is provided in each of the stacked portions 20L and 20U of the stairs region 200 as shown in FIG. 6B of the first embodiment, and each of a plurality of contacts 80 similar to those shown in FIG. 6B is connected to a respective conductive layer 21 of the plurality of conductive layers 21 in the stairs portion 20STC, as in the case of the first embodiment.

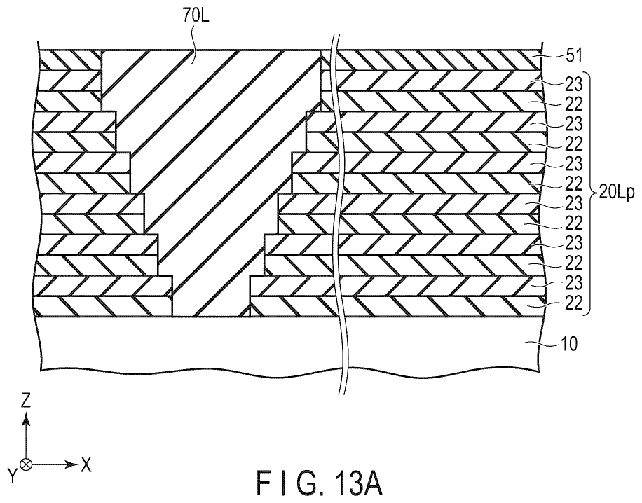

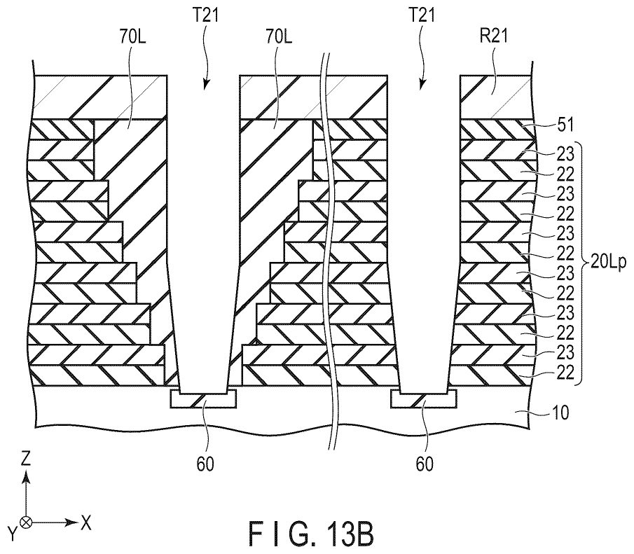

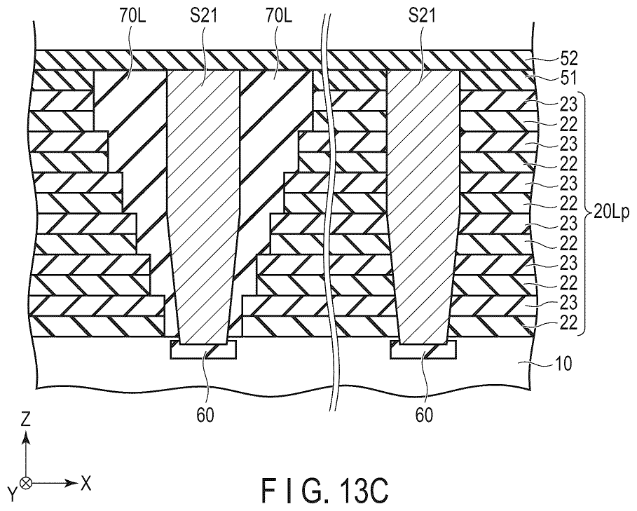

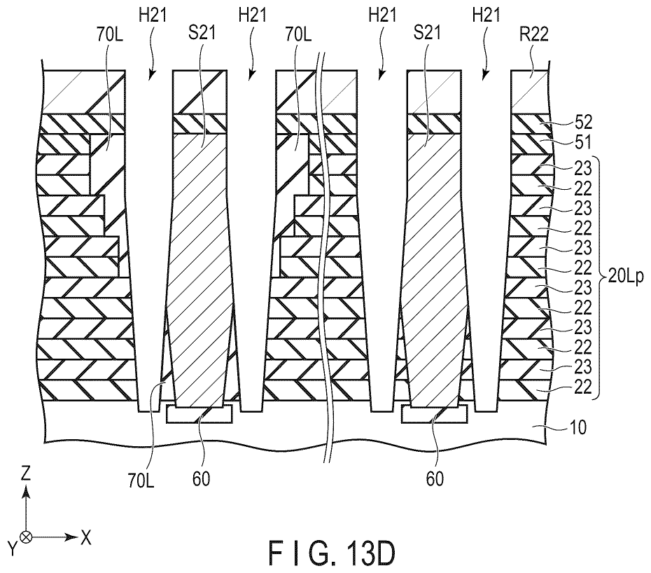

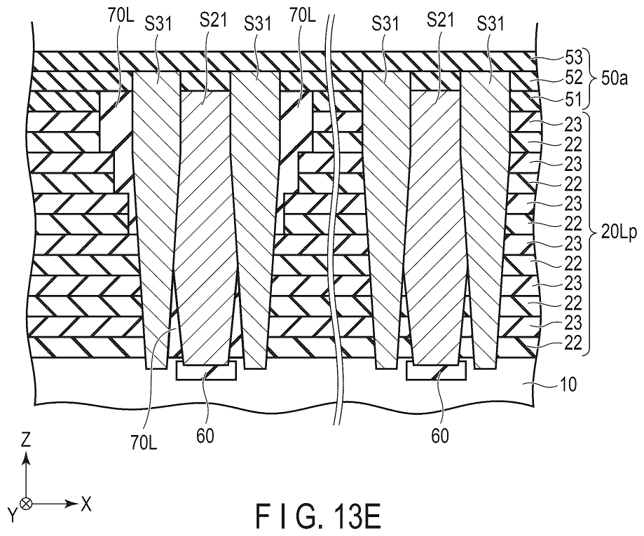

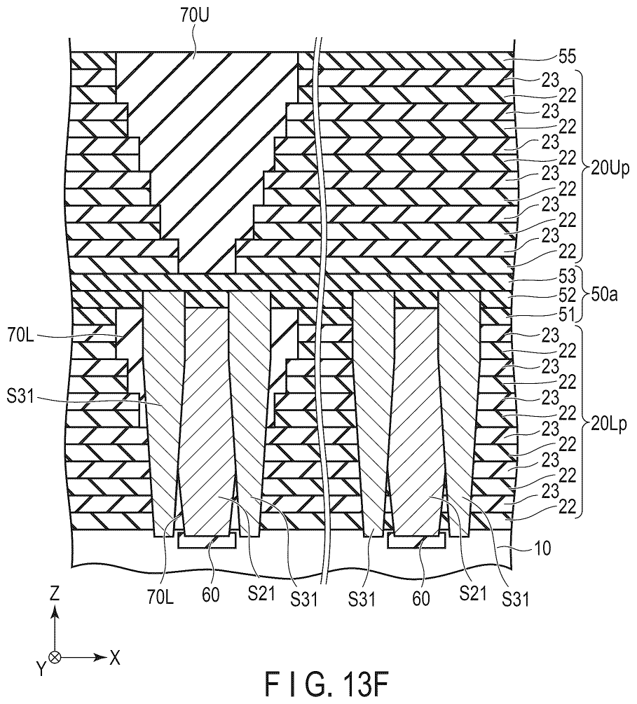

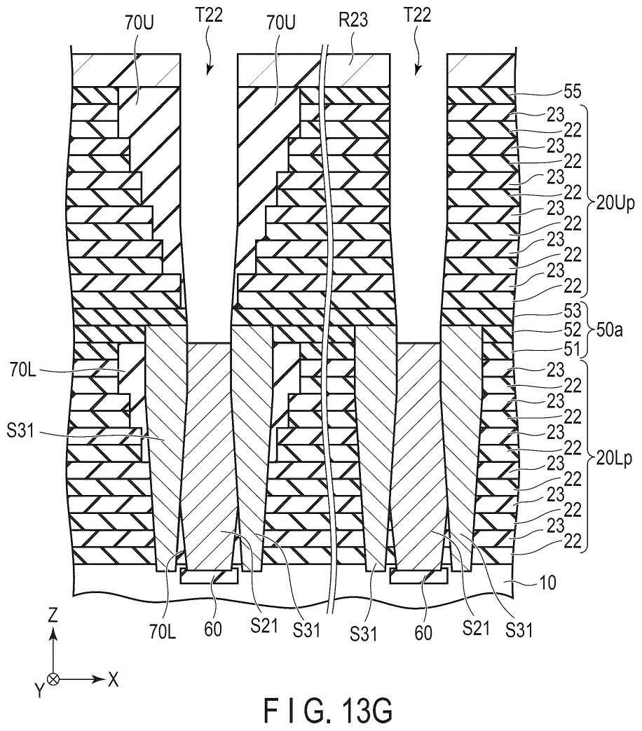

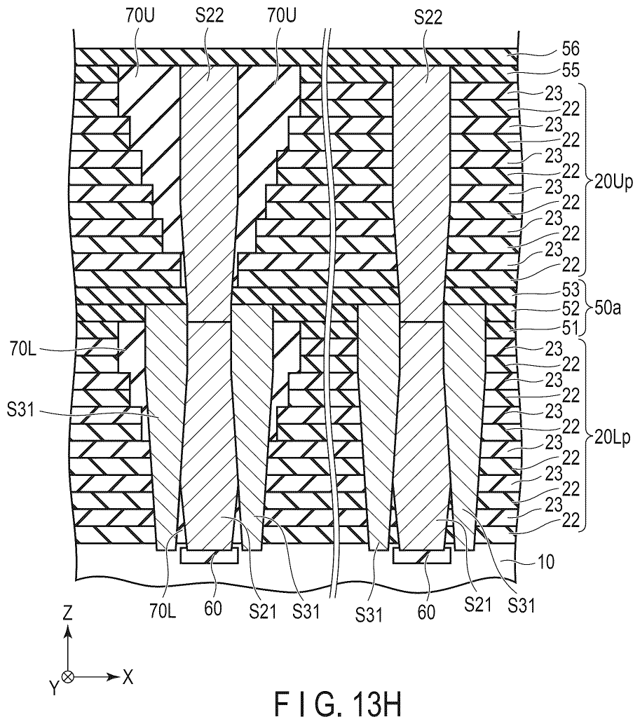

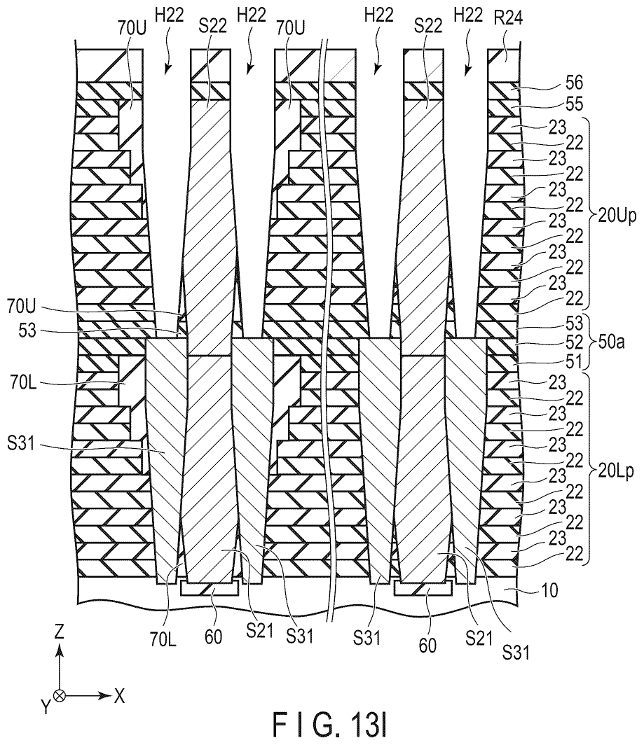

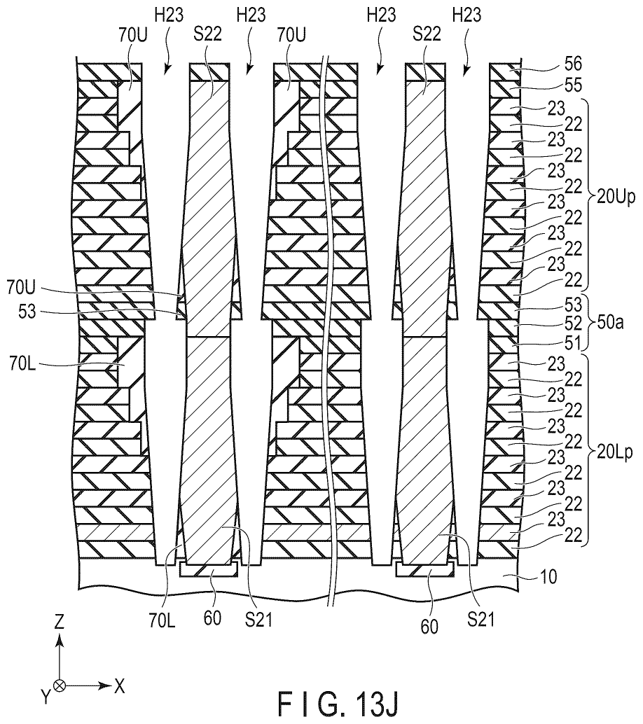

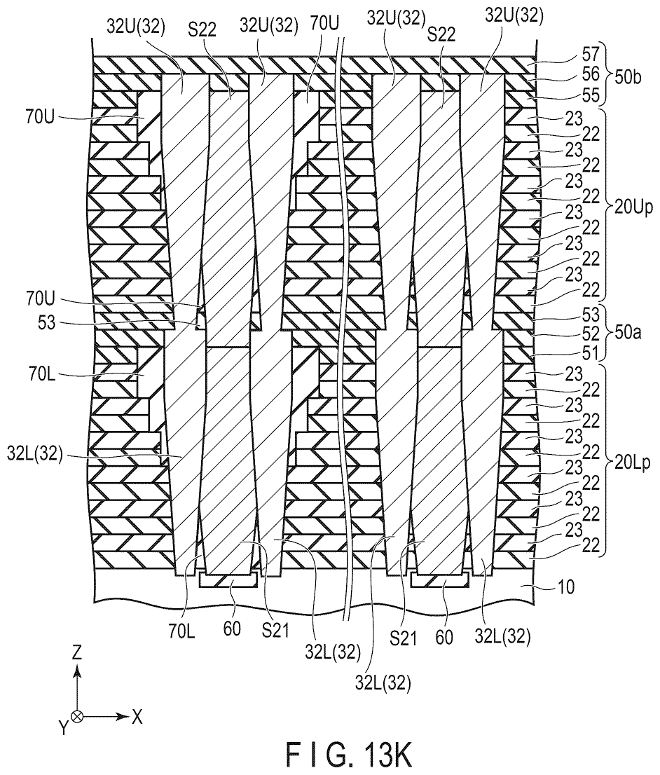

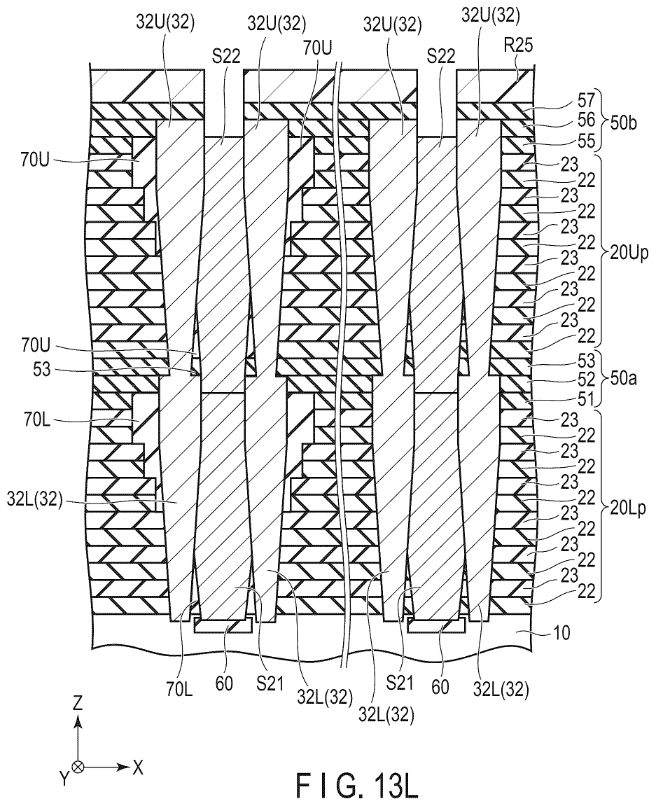

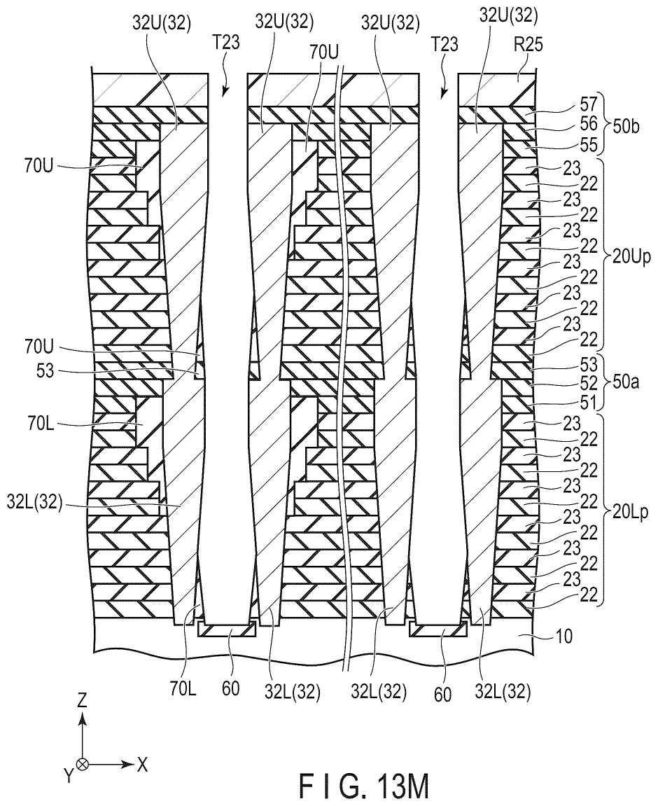

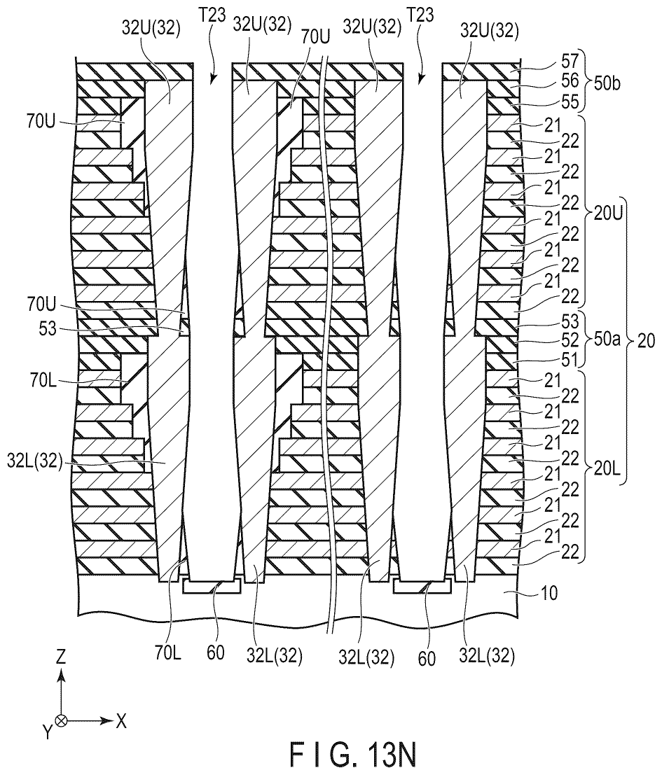

Next, a method of manufacturing the semiconductor memory device of this embodiment will be explained with reference to FIGS. 13A to 13N. Note that FIGS. 13A to 13N each schematically show a respective step in the process of formation of the stairs region 200. In the following descriptions, the memory region will not be described, but as in the case of the first embodiment, a common formation step to the formation process for the stairs region 200 is used for the memory region as well.

The processing step in FIG. 13A is similar to the processing step in FIG. 10A of the first embodiment. That is, a structure including a preliminary stacked portion 20Lp, an insulating layer 51, and an insulating layer 70L is formed on the lower region 10.

The processing step in FIG. 13B as well is similar to the processing step in FIG. 10B of the first embodiment. That is, using the resist pattern R21 as a mask, the preliminary stacked portion 20Lp, insulating layer 51, and insulating layer 70L are etched by RIE to form a trench T21 that extends in the Y direction.

The processing step in FIG. 13C is similar to the processing step in FIG. 10C of the first embodiment. That is, a structure is formed in which the trench T21 is filled with the sacrificial layer S21, and then the insulating layer 52 is formed.

The processing step in FIG. 13D as well is similar to the processing step in FIG. 10D of the first embodiment. That is, using the resist pattern R22 as a mask, the preliminary stacked portion 20Lp, the insulating layers 51, 52 and 70L are etched by RIE to form holes H21.

Next, as shown in FIG. 13E, a sacrificial layer S31 is formed in the hole H21. Carbon is used for the sacrificial layer S31. A part of the side surface of the sacrificial layer S21 is exposed in the etching process shown in FIG. 13D, the part of the side surface of the sacrificial layer S21 and the part of the side surface of the sacrificial layer S31 are conformed to each other. Further, an insulating layer 53 is formed on the structure thus obtained.

Next, as shown in FIG. 13F, a processing step similar to the processing step in FIG. 13A is performed to form a structure including a preliminary stacked portion 20Up, an insulating layer 55, and an insulating layer 70U on the structure obtained by the processing step in FIG. 13E.

Next, as shown in FIG. 13G, a processing step similar to the processing step in FIG. 13B is performed to etch the preliminary stacked portion 20Up, insulating layer 52, insulating layer 53, insulating layer 55, and insulating layer 70U by RIE using a resist pattern R23 as a mask, to form a trench T22 that extends in the Y direction. In this etching process, the upper surface of the sacrificial layer S21 is exposed.

Next, as shown in FIG. 13H, a processing step similar to the processing step in FIG. 13C is performed to form a structure in which the trench T22 is filled with the sacrificial layer S22. Amorphous silicon is used for the sacrificial layer S22 similar to the sacrificial layer S21. Further, an insulating layer 56 is formed on the structure thus obtained.

Next, as shown in FIG. 13I, a processing step similar to the processing step in FIG. 13D is performed. That is, using the resist pattern R24 as a mask, the preliminary stacked portion 20Up, insulating layer 53, insulating layer 55, insulating layer 56, and insulating layer 70U are etched by RIE to form holes H22. By this etching process, the upper surface of the sacrificial layer S31 is exposed.

Next, as shown in FIG. 13J, the sacrificial layer S31 is removed by ashing. Thus, holes H23 that reach the lower region 10 are formed.

Next, as shown in FIG. 13K, a pillar structure 32 including a pillar structure portion 32L and a pillar structure portion 32U is formed in the hole H23. A part of the side surface of the sacrificial layer S21 and a part of the side surface of the sacrificial layer S22 are exposed by the hole H23, and therefore the part of the side surface of the pillar structure portion 32L is conformed to the part of the side surface of the sacrificial layer S21, and the part of the side surface of the pillar structure portion 32U is conformed to the part of the side surface of the sacrificial layer S22. Then, an insulating layer 57 is formed on the structure thus obtained.

Next, as shown in FIG. 13L, the insulating layers 56 and 57 are etched using the resist pattern R25 as a mask. Thus, the upper surface of the sacrificial layer S22 is exposed.

Next, as shown in FIG. 13M, the sacrificial layers S21 and S22 are removed by wet etching to form trench T23 that reaches the lower region 10. Thus, the part of the side surface of the pillar structure portion 32L and the part of the side surface of the pillar structure portion 32U are exposed.

Next, as shown in FIG. 13N, a plurality of sacrificial layers 23 are etched via the trench T23 to form a plurality of spaces. Further, the spaces are filled with a plurality of conductive layers 21 such as tungsten layers. In this manner, the replacement process, in which the sacrificial layers 23 are replaced by the conductive layers 21, is completed. As a result, a stacked body 20 is formed, in which a plurality of conductive layers 21 and a plurality of insulating layers 22 are stacked alternately.

After that, the trench T23 is filled with a metal material such as tungsten, and thus a structure as shown in FIG. 12 is obtained. In the memory region 100, a structure as shown in FIG. 11 is obtained. Further, contacts 80 similar to those shown in FIG. 6B of the first embodiment are formed.

As described above, in this embodiment as well, the pillar structure 32, which is provided in the stairs region 200 and does not function as a NAND string, includes a part that is not substantially apart from the plate-shaped structure 40 adjacent thereto as in the case of the first embodiment. That is, a part of the side surface of the plate-shaped structure 40L is conformed to a part of the side surface of the pillar structure 32L, and includes a recess portion based on the part of the side surface of the pillar structure 32L. Similarly, a part of the side surface of the plate-shaped structure portion 40U is conformed to a part of the side surface of the pillar structure portion 32U, and includes a recess portion based on the part of the side surface of the pillar structure portion 32U. Therefore, as in the case of the first embodiment, the pillar structure 32 can be provided adjacent to the plate-shaped structure 40, and the degree of integration of the semiconductor memory device can be increased. Further, in the pillar structure 32 provided adjacent to the plate-shaped structure 40, the function of supporting the preliminary stacked portions 20Lp and 20Up in which a plurality of spaces are formed is enhanced during the replacement process.

In this embodiment as well, the basic configuration of the pillar structure 32 provided in the stairs region 200 is same as the basic configuration of the pillar structure 31 provided in the memory region 100 and functioning as a NAND string as in the case of the first embodiment. Thus, it is possible to form the pillar structure 32 in a common process to that of the pillar structure 31.

Further, in this embodiment as well, sacrificial layers S21 and S22 are formed in advance in the region where the plate-shaped structure 40 is to be formed, the pillar structure 32 is formed in the state where the sacrificial layers S21 and S22 are formed, and after that, the plate-shaped structure 40 is formed in the trench T23 obtained by removing the sacrificial layers S21 and S22 as in the first embodiment. Therefore, it is possible to precisely form the pillar structure 32 and the plate-shaped structure 40 as in the case of the first embodiment. Further, by forming the pillar structure 32, which includes the semiconductor layer 32a that is difficult to shrink even by thermal treatment or the like, it is possible to suppress the sinking of the structural body including the stacked body 20 and the insulating layers 70L and 70U in the stairs region 200.

### Third Embodiment

Next, a semiconductor memory device (NAND-type nonvolatile semiconductor memory device) according to the third embodiment will be explained. Note that the basic items are similar to those of the first and second embodiments, and the explanation of the items already described in the first and second embodiments is omitted.

The overall configuration of the semiconductor memory device in this embodiment is similar to that shown in FIG. 1, and the explanation thereof is omitted here.

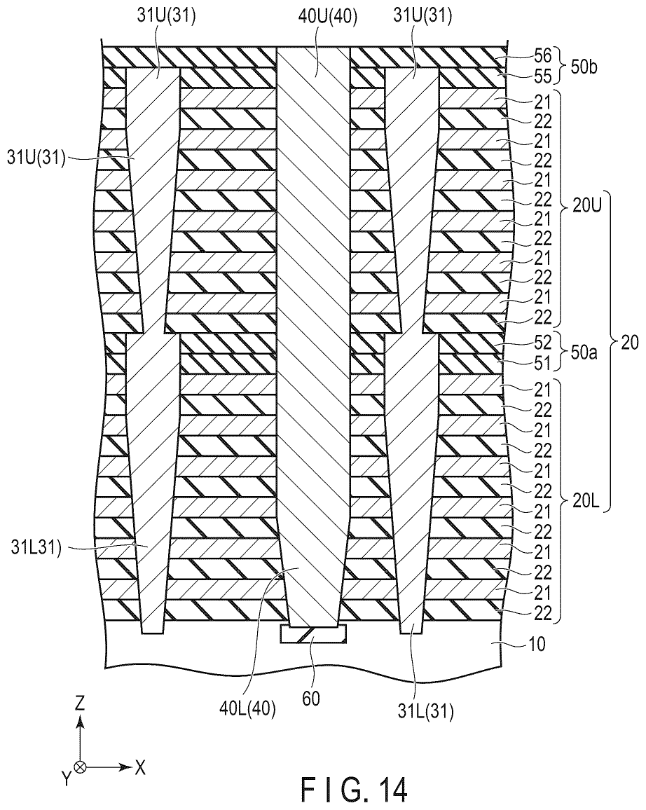

FIG. 14 is a schematic cross-sectional view showing a part of a configuration of the memory region 100. The schematic planar pattern of the part of the configuration of the memory region 100 is similar to that shown in FIG. 3 of the first embodiment, and therefore the illustration by a figure is omitted.

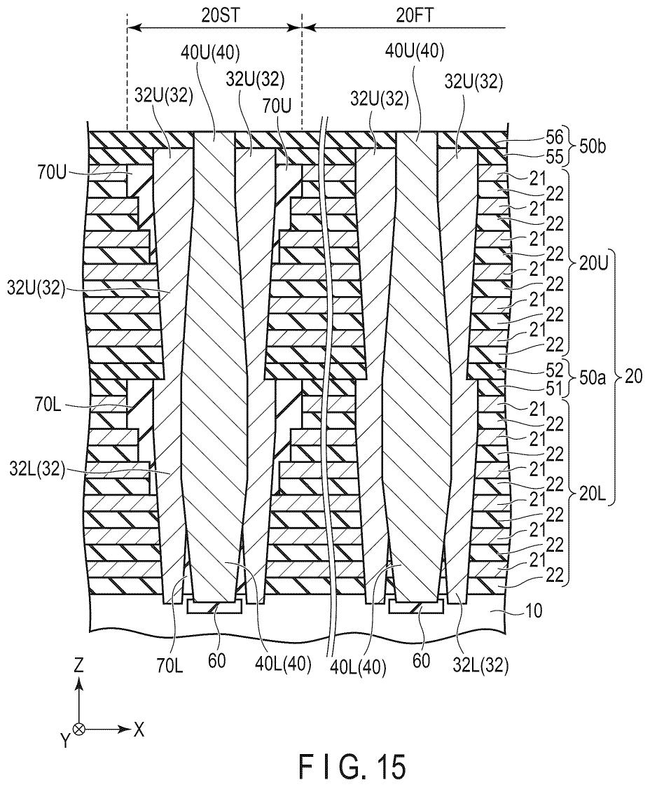

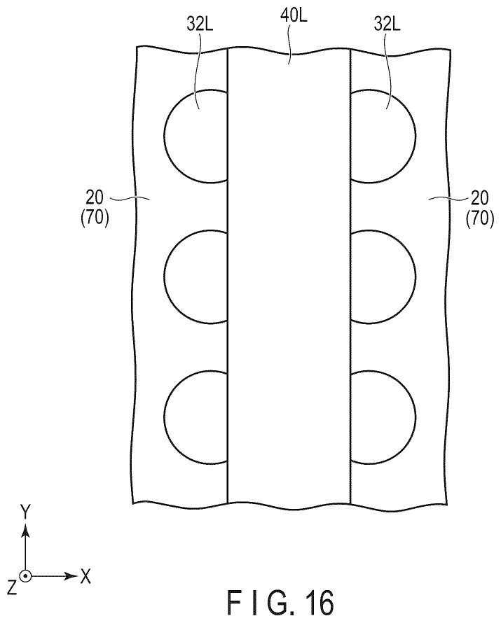

FIG. 15 is a cross-sectional view schematically showing a part of the configuration of the stairs region 200. FIG. 16 is a planar pattern diagram schematically showing a part of the configuration of the stairs region 200 (specifically, a part of the configuration of the region where the pillar structure portion 32L and the plate-shaped structure portion 40L are provided).

As shown in FIGS. 15 and 16, in this embodiment as well, the stacked body 20 includes a stacked portion 20L and a stacked portion 20U, and the plate-shaped structure 40 includes a plate-shaped structure portion 40L and a plate-shaped structure portion 40U as in the case of the second embodiment. Further, in the memory region 100, the pillar structure 31 includes a pillar structure portion 31L and a pillar structure portion 31U, and in the stairs region 200, the pillar structure 32 includes a pillar structure portion 32L and a pillar structure portion 32U.

The basic structure and basic functions of each of the stacked body 20, pillar structure 31, pillar structure 32 and plate-shaped structure 40 are similar to those of the first embodiment.

Further, in this embodiment as well, in the stairs region 200, a flat portion 20FT and a stairs portion 20ST are provided in each of the stacked portion 20L and stacked portion 20U, as in the case of the second embodiment. The end portion of the stairs portion 20ST of the stacked portion 20L is covered by an insulating layer 70L, and the end portion of the stairs portion 20ST of the stacked portion 200 is covered by an insulating layer 70U.

Further, in this embodiment, an intermediate insulating portion 50a is provided between the stacked portion 20L and the stacked portion 200 as in the case of the second embodiment. The intermediate insulating portion 50a includes insulating layers 51 and 52. The thickness of the intermediate insulating portion 50a is greater than the thickness of the conductive layer 21 and the thickness of the insulating layer 22. Further, an upper insulating portion 50b is provided on the stacked portion 20U, the pillar structure portion 31U, and the pillar structure portion 32U. The upper insulating portion 50b includes insulating layers 55 and 56. The insulating layers 51, 52, 55, and 56 are formed of silicon oxide or the like.

The relationship between the stacked portion 20L, pillar structure portion 31L and plate-shaped structure portion 40L, and the relationship between the stacked portion 20U, pillar structure portion 31U and plate-shaped structure portion 40U are both similar to the relationship between the stacked body 20, pillar structure 31 and plate-shaped structure 40 in the first embodiment. Therefore, the configuration of the pillar structure portion 31L and the like and the configuration of the pillar structure portion 31U and the like in the memory region 100 are both similar to the configuration of the pillar structure 31 and the like in the first embodiment shown in FIGS. 4 and 5.

The relationship between the stacked portion 20U, pillar structure portion 32U, plate-shaped structure portion 40U and insulating layer 70U as well is similar to the relationship between the stacked body 20, pillar structure 32, plate-shaped structure 40 and insulating layer 70 of the first embodiment. Therefore, the configuration of the pillar structure portion 32U and the like in the stairs region 200 is similar to the configuration of the pillar structure 32 and the like in the first embodiment shown in FIGS. 8 and 9.

The basic relationship between the stacked portion 20L, the pillar structure portion 32L, the plate-shaped structure portion 40L and the insulating layer 70L as well is similar to the relationship between the stacked body 20, the pillar structure 32, the plate-shaped structure 40 and the insulating layer 70 of the first embodiment. However, in this embodiment, the relationship between the pillar structure portion 32L and the plate-shaped structure portion 40L is slightly different from the relationship between the pillar structure 32 and the plate-shaped structure 40 in the first embodiment.

In this embodiment, a part of the side surface of the pillar structure portion 32L (which is also a part of the side surface of the pillar structure 32) is conformed to a part of the side surface of the plate-shaped structure portion 40L (which is also a part of the side surface of the plate-shaped structure 40), and includes a flat surface based on the part of the side surface of the plate-shaped structure portion 40L (a flat surface based on the shape of the part of the side surface of the plate-shaped structure portion 40L). Specifically, the part of the side surface of the pillar structure portion 32L is conformed to the part of the side surface along the Y direction and the Z direction of the plate-shaped structure portion 40L, and includes a flat surface based on the part of the side surface of the plate-shaped structure portion 40L. That is, the side surface of the plate-shaped structure portion 40L is substantially a flat surface, and therefore the part of the side surface of the pillar structure portion 32L has a flat shape based on the flat shape of the side surface of the plate-shaped structure portion 40L.

In other words, the flat surface of the side surface of the pillar structure portion 32L described above is included at least in an region corresponding to the range between a height level corresponding to a height level of the upper surface of the stacked portion 20L and a height level corresponding to a height level of the lower surface of the stacked portion 20L.

Further, from another perspective, as shown in FIG. 16, the pattern of the pillar structure portion 32L includes a straight line portion based on the pattern of the plate-shaped structure portion 40L when viewed in the Z direction. For example, when viewed in the Z direction, the pattern of the pillar structure portion 32L has such a planar shape that a part of a circle or ellipse is cut out along a straight line extending in the Y direction. That is, when viewed in the Z direction, the pattern of the pillar structure portion 32L has such a planar shape that a part of a pattern of the circular or elliptical shape is cut out according to the pattern of the plate-shaped structure portion 40L.

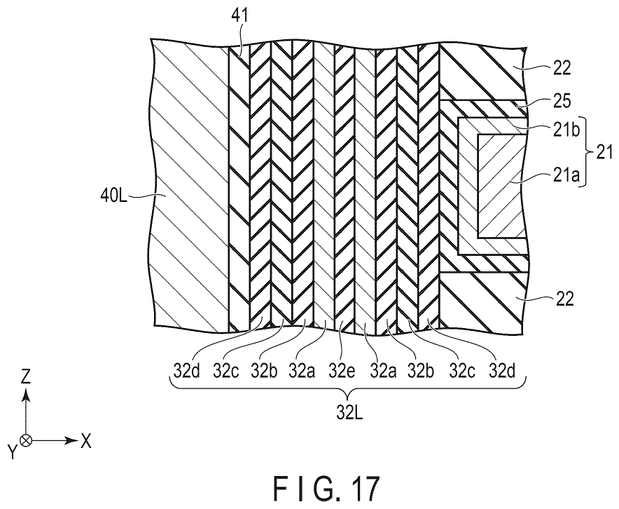

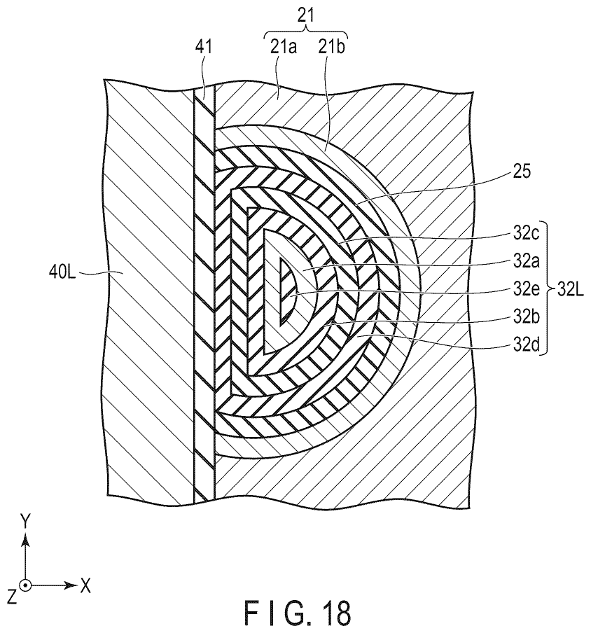

FIGS. 17 and 18 are cross-sectional views each schematically showing a detailed configuration of the pillar structure portion 32L and the like in the flat portion 20FT of the stacked body 20. FIG. 17 is a cross-sectional view parallel to the Z direction, and FIG. 18 is a cross-sectional view perpendicular to the Z direction. The basic configuration of the pillar structure portion 32L in the stairs portion 20ST of the stacked body 20 as well is similar to the configuration of the pillar structure portion 32L shown in FIGS. 17 and 18.

The shape of the pillar structure portion 32L in this embodiment is different from the shape of the pillar structure 32 in the first embodiment shown in FIGS. 8 and 9, but the basic structure of the pillar structure portion 32L is similar to the structure of the pillar structure 32 shown in FIGS. 8 and 9. That is, as in the case of the pillar structure 32 shown in FIGS. 8 and 9, the pillar structure portion 32L includes a semiconductor layer 32a, a tunnel insulating layer 32b, a charge storage layer 32c, a block insulating layer 32d, and a core insulating layer 32e, and these layers 32a to 32e extend in the Z direction. When viewed in the Z direction, the plurality of the layers 32a, 32b, 32c, and 32d of the pillar structure portion 32L which surround the innermost core insulating layer 32e each have a planar shape that extends continuously along the entire circumference of such a planner shape of the pillar structure portion 32L that a part of a circle or ellipse is cut out (along a part of the side surface of the pillar structure portion 32L, which is conformed to the part of the side surface of the plate-shaped structure portion 40L and has a flat shape) without being cut off on a side facing the plate-shaped structure portion 40L. Further, the plurality of the layers 32a to 32e are stacked from an outer peripheral surface side of the pillar structure portion 32L, which includes the part of the flat side surface facing the plate-shaped structure portion 40L, toward an inner side of the pillar structure portion 32L, in the same stacking order of the pillar structure 32 shown in FIGS. 8 and 9.

Note that though not particularly shown in the figures, in this embodiment as well, stairs portion 20STC is provided in the stacked portions 20L and 20U of the stairs region 200 as shown in FIG. 6B of the first embodiment, and each of a plurality of contacts 80 similar to those shown in FIG. 6B is connected to a respective conductive layer 21 of the plurality of conductive layers 21 in the stairs portions 20STC, as in the case of the first embodiment.

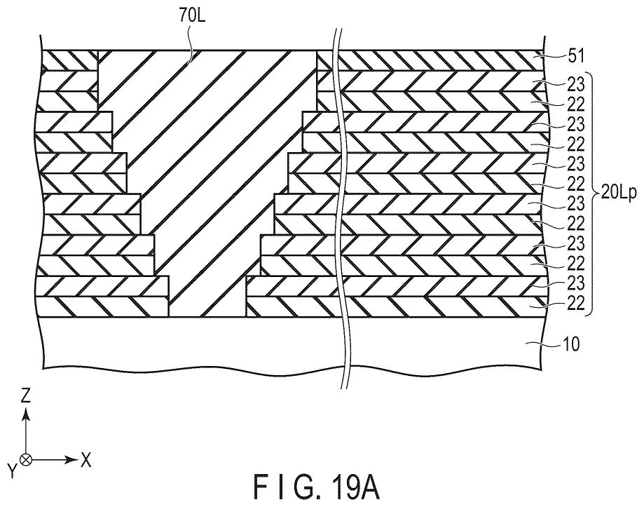

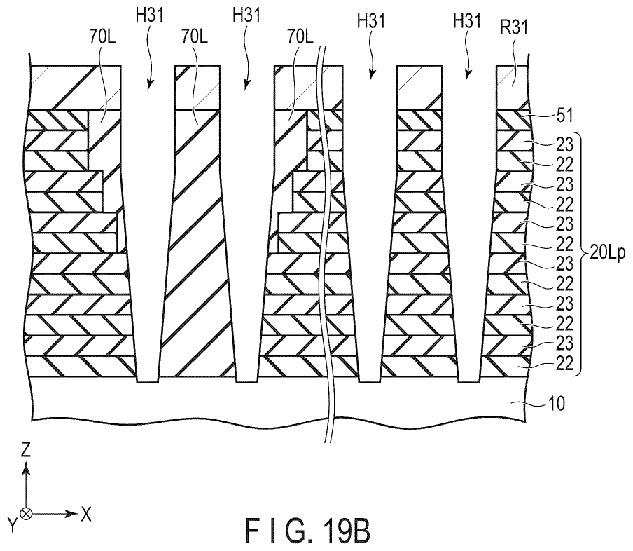

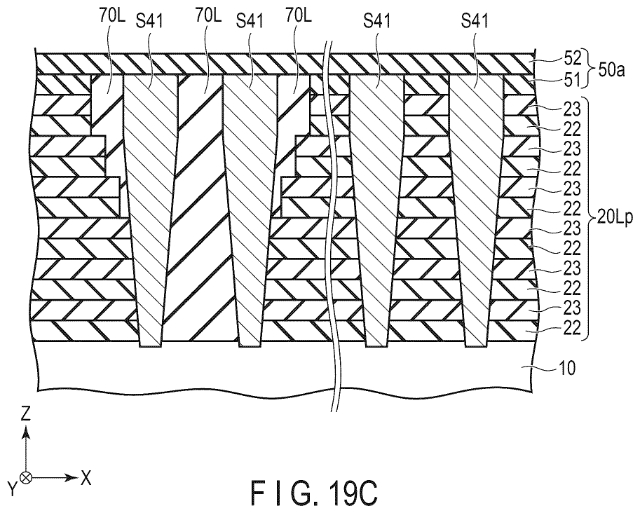

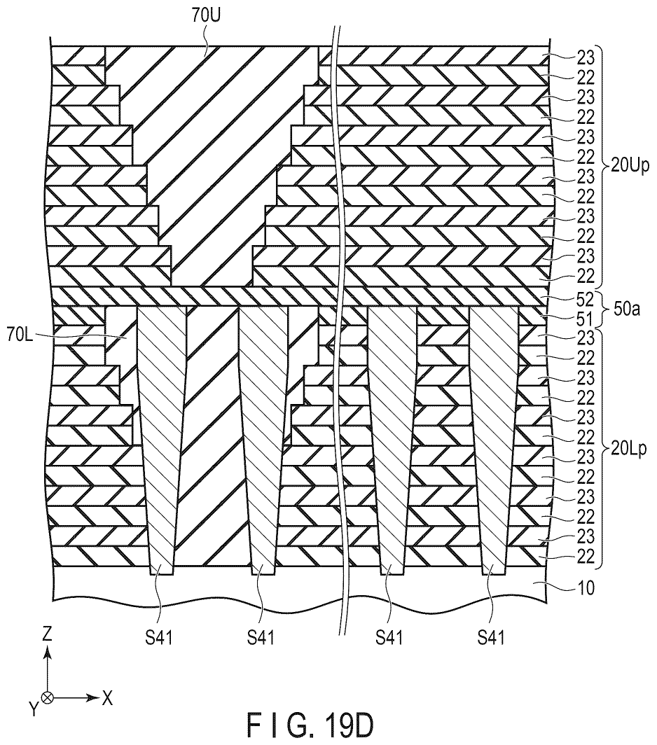

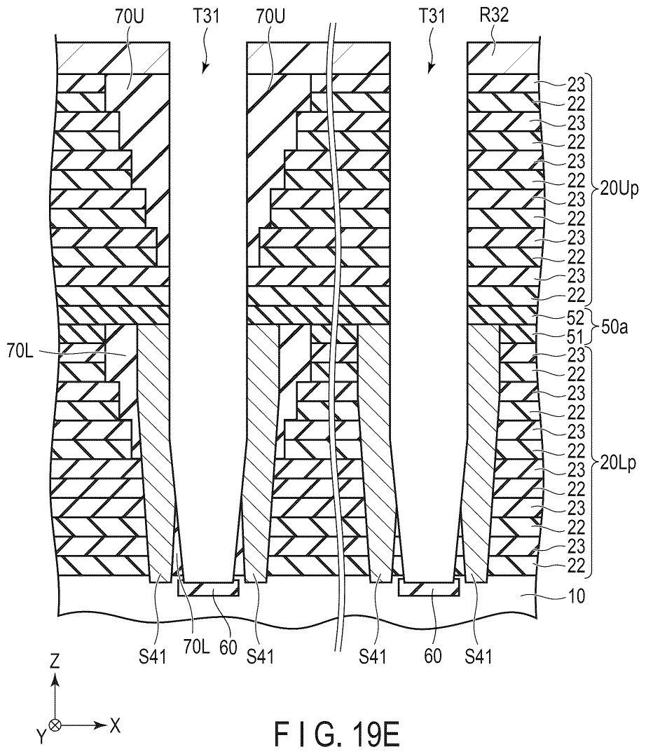

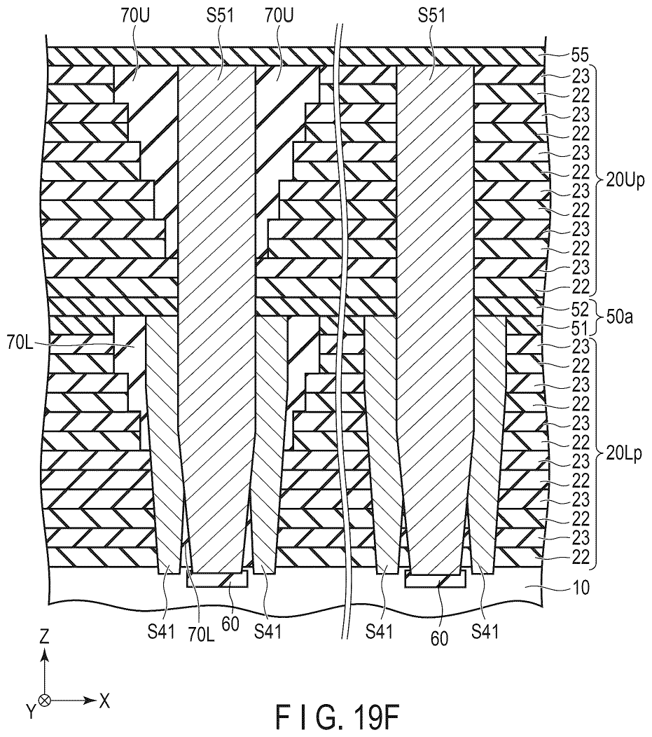

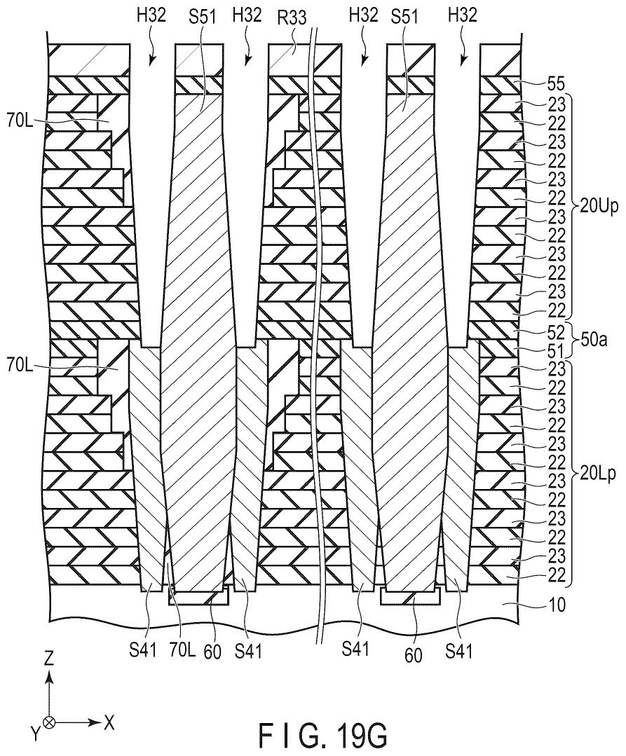

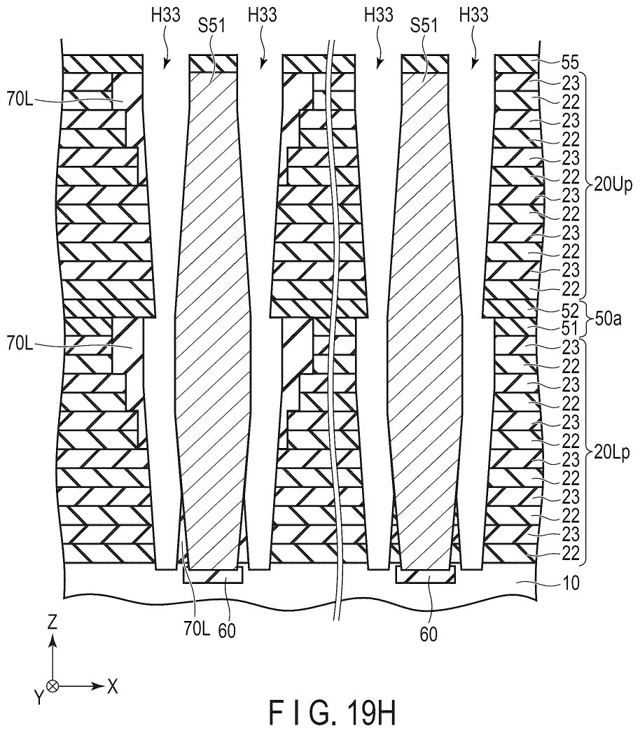

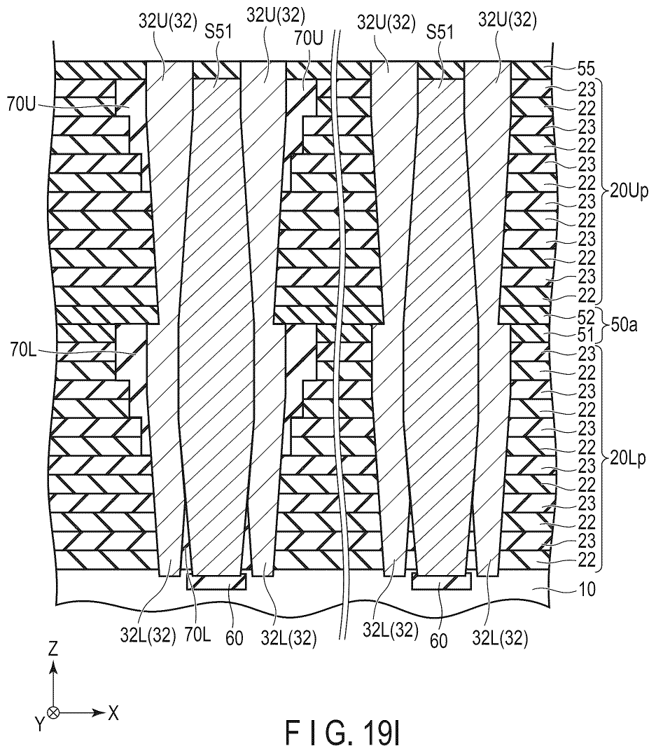

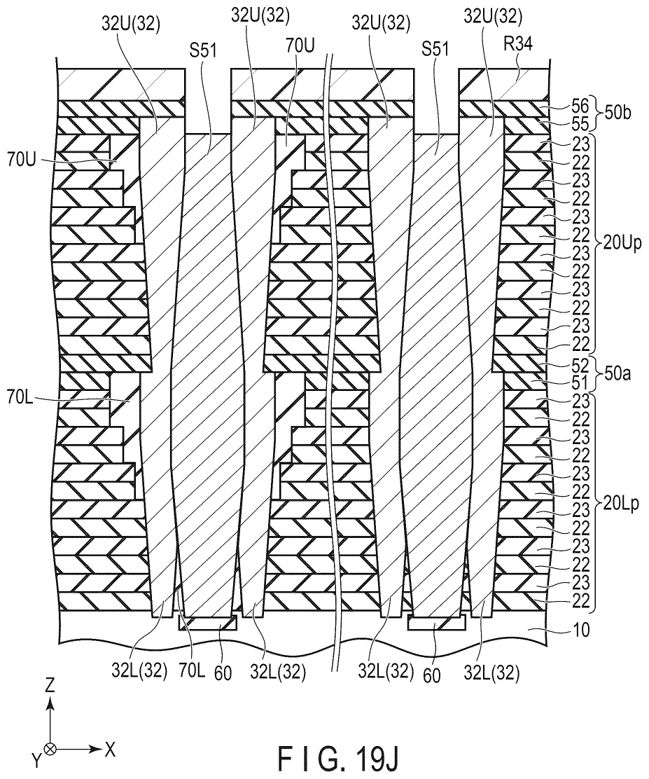

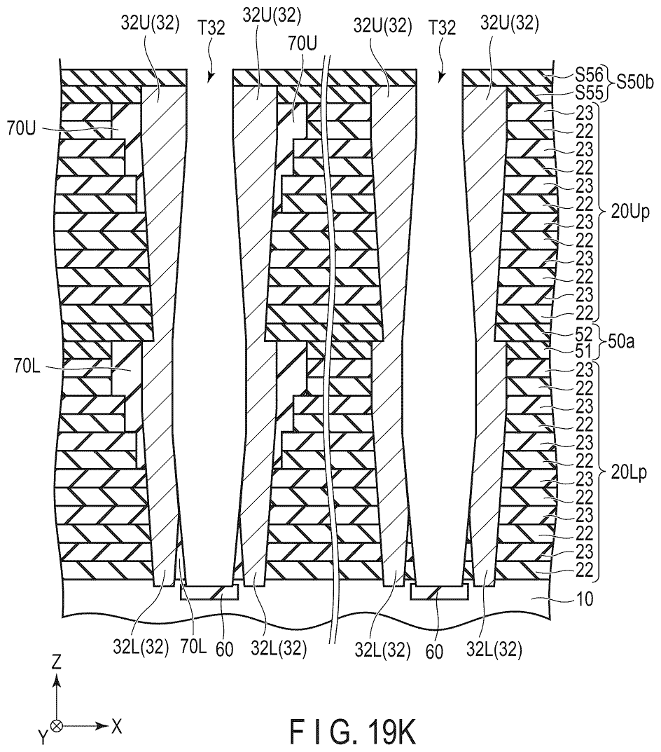

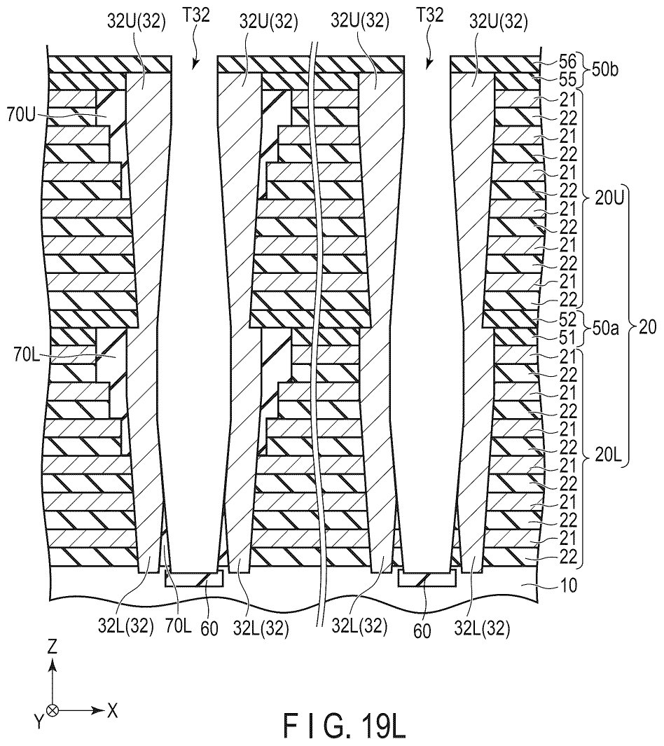

Next, a method of manufacturing the semiconductor memory device of this embodiment will be explained with reference to FIGS. 19A to 19L. FIGS. 19A to 19L each schematically show a respective processing step in the formation of the stairs region 200. In the following descriptions, the memory region is not referred to, as in the first embodiment, a common formation process to that of the stairs region 200 is performed in the formation of the memory region. The processing step in FIG. 19A is similar to the processing step shown in FIG. 10A of the first embodiment. That is, a structure including a preliminary stacked portion 20Lp, an insulating layer 51 and an insulating layer 70L is formed on the lower region 10.

Next, as shown in FIG. 19B, the preliminary stacked portion 20Lp, insulating layer 51, and insulating layer 70L are etched by RIE using a resist pattern R31 as a mask to form holes H31. At this time, the surface area of the lower region 10 is also etched, and the bottom surfaces of the holes H31 become lower in level than the upper surface of the lower region 10.

Next, as shown in FIG. 19C, the holes H31 are filled with a sacrificial layer S41. For the sacrificial layer S41, a metal material such as tungsten or titanium is used. Further, an insulating layer 52 is formed on the structure thus obtained.

Next, as shown in FIG. 19D, a process similar to that shown in FIG. 19A is performed to form a structure including a preliminary stacked portion 20Up and an insulating layer 70U on the structure obtained in the processing step of FIG. 19C.

Next, as shown in FIG. 19E, using a resist pattern R32 as a mask, the preliminary stacked portion 20Lp and preliminary stacked portion 20Up, insulating layer 51, insulating layer 52, insulating layer 70L, and insulating layer 70U are etched by RIE to form a trench T31 that extends in the Y direction. In this etching process, a part of the sacrificial layer S41 is also etched, and the shape of the sacrificial layer S41 is changed. Further, the surface area of the lower region 10 is also etched, and the location of the bottom surface of the trench T31 becomes lower than the location of the upper surface of the lower region 10. Furthermore, an insulating portion 60 is formed near the bottom surface of the trench T31.

Next, as shown in FIG. 19F, the trench T31 is filled with a sacrificial layer S51. For the sacrificial layer S51, amorphous silicon is used. Further, an insulating layer 55 is formed on the structure thus obtained.

Next, as shown in FIG. 19G, using a resist pattern R33 as a mask, the preliminary stacked portion 20Up, insulating layer 52, insulating layer 55, and insulating layer 70U are etched by RIE to form holes H32 that reach the sacrificial layer S41. In this etching process, a part of the sacrificial layer S51 is also etched, and the shape of an upper portion of the sacrificial layer S51 is changed.

Next, as shown in FIG. 19H, the sacrificial layer S41 is etched to form holes H33 that reach the lower region 10. With this etching process, a part of the side surface of the lower portion of the sacrificial layer S51 is exposed.

Next, as shown in FIG. 19I, a pillar structure 32 which includes a pillar structure portion 32L and a pillar structure portion 32U is formed in the hole H33. Here, a part of the side surface of the sacrificial layer S51 is exposed by the hole H33, and therefore the part of the side surface of the pillar structure 32 is conformed to the part of the side surface of the sacrificial layer S51.

Next, as shown in FIG. 19J, an insulating layer 56 is formed on the structure obtained in the processing step shown in FIG. 19I. Further, using a resist pattern R34 as a mask, the insulating layer 55 and the insulating layer 56 are etched to expose the upper surface of the sacrificial layer S51.

Next, as shown in FIG. 19K, the sacrificial layer S51 is removed by wet etching to form trench T32 that reaches the lower region 10. With this process, a part of the side surface of the pillar structure 32 is exposed.

Next, as shown in FIG. 19L, a plurality of sacrificial layers 23 are etched via the trench T32 to form a plurality of spaces. Further, the plurality of spaces are filled with a plurality of conductive layers 21 such as tungsten layers. Thus, the replacement process, in which the sacrificial layers 23 are replaced by the conductive layers 21, is completed. As a result, a stacked body 20 is formed, in which the plurality of conductive layers 21 and the plurality of insulating layers 22 are stacked alternately.

After that, by filling the trench T32 with a metal material such as tungsten, such a structure as shown in FIG. 15 is obtained. In the memory region 100, such a structure as shown in FIG. 14 is obtained. Further, contacts 80 similar to those shown in FIG. 6B of the first embodiment are formed.

As described above, in this embodiment, the pillar structure 32, which is provided in the stairs region 200 and does not function as a NAND string, includes a part that is not substantially apart from the plate-shaped structure 40 adjacent thereto, as in the case of the first embodiment. That is, a part of the side surface of the plate-shaped structure portion 40U is conformed to a part of the side surface of the pillar structure portion 32U, and includes a recess portion based on the part of the side surface of the pillar structure portion 32U. In addition, the part of the side surface of the pillar structure portion 32L is conformed to the part of the side surface of the plate-shaped structure portion 40L, and includes a flat surface based on the part of the side surface of the plate-shaped structure portion 40L. With this configuration, the pillar structure 32 can be provided adjacent to the plate-shaped structure 40, and the degree of integration of the semiconductor memory device can be increased as in the case of the first embodiment. In addition, in the pillar structure 32 provided adjacent to the plate-shaped structure 40, the function of supporting the preliminary stacked portions 20Lp and 20Up in which a plurality of spaces are formed is enhanced during the replacement process.

In this embodiment as well, the basic configuration of the pillar structure 32 provided in the stairs region 200 is same as the basic configuration of the pillar structure 31 provided in the memory region 100 and functioning as a NAND string. Therefore, it is possible to form the pillar structure 32 in a common processing step to the pillar structure 31.

Further, in this embodiment as well, a sacrificial layer S51 is formed in advance in the area where the plate-shaped structure 40 is to be formed, the pillar structure 32 is formed in the state where the sacrificial layer S51 is formed, and thereafter, the plate-shaped structure 40 is formed in the trench T32 obtained by removing the sacrificial layer S51 as in the case of the first embodiment. Therefore, it is possible to precisely form the pillar structure 32 and the plate-shaped structure 40 as in the case of the first embodiment. Further, by forming the pillar structure 32, which includes the semiconductor layer 32a that is difficult to shrink even by thermal treatment and the like, it is possible to suppress the sinking of the structural body including the stacked body 20 and the insulating layers 70L and 70U in the stairs region 200.

Note that the configuration of the pillar structure 32 provided in the stairs region 200 in each of the embodiments is not limited to a stairs structure processed into a valley-like shape from the outer side to the inner side, and can be applied to other stairs structure. For example, a pillar structure 32 similar to that in each of the embodiments described above may be provided in the stairs region 200, in which stairs leading up to the memory region 100 are provided on one or both sides of the memory region 100 in the Y direction. In any case where the above described pillar structure is applied to any one of the stairs structures, the plurality of pillar structures 31 and the plurality of pillar structures 32 provided respectively in the memory region 100 and stairs region 200, which are arranged in the Y direction, do not overlap each other when viewed in the X direction.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A semiconductor memory device comprising:
a structural body including a stacked body in which a plurality of conductive layers are stacked to be apart from each other in a first direction;
a plate-shaped structure extending in the first direction and a second direction that intersects the first direction in the structural body to at least a height level corresponding to a height level of a lower surface of the stacked body;
a first pillar structure extending in the first direction in the stacked body and functioning as a NAND string, the first pillar structure having a structure in which a plurality of layers including a first semiconductor layer and extending in the first direction are stacked from an outer peripheral surface side toward an inner side; and
a second pillar structure extending in the first direction in the structural body and not functioning as a NAND string, the second pillar structure having a structure in which a plurality of layers including a second semiconductor layer and extending in the first direction are stacked from an outer peripheral surface side toward an inner side,
wherein
materials of the plurality of layers stacked from the outer peripheral surface side toward the inner side in the second pillar structure are respectively same as materials of the plurality of layers stacked from the outer peripheral surface side toward the inner side in the first pillar structure, and
a part of a side surface of the plate-shaped structure is conformed to a part of a side surface of the second pillar structure and includes a recess portion based on the part of the side surface of the second pillar structure.

2. The device of claim 1, wherein
the stacked body includes a first stacked portion in which a plurality of first conductive layers of the plurality of conductive layers are stacked in the first direction, and a second stacked portion which is provided on an upper layer side of the first stacked portion and in which a plurality of second conductive layers of the plurality of conductive layers are stacked in the first direction, and
the recess portion is included at least in a region corresponding to a range between a height level corresponding to a height level of an upper surface of the first stacked portion and a height level corresponding to a height level of a lower surface of the first stacked portion.

3. The device of claim 1, wherein
the stacked body includes a first stacked portion in which a plurality of first conductive layers of the plurality of conductive layers are stacked in the first direction, and a second stacked portion which is provided on an upper layer side of the first stacked portion and in which a plurality of second conductive layers of the plurality of conductive layers are stacked in the first direction, and
the recess portion is included at least in a region corresponding to a range between a height level corresponding to a height level of an upper surface of the second stacked portion and a height level corresponding to a height level of a lower surface of the second stacked portion.

4. The device of claim 1, wherein
the first pillar structure is apart from the plate-shaped structure.

5. The device of claim 1, wherein
when viewed in the first direction, the second pillar structure has a pattern of a circular or elliptical planar shape.

6. The device of claim 1, wherein
the stacked body includes a first stairs portion processed in a stair-like manner along a third direction that intersects the first direction and the second direction, and a flat portion extending in the third direction from an uppermost surface of the first stairs portion in a flat manner, and
the second pillar structure extends in the first direction in the flat portion.

7. The device of claim 1, wherein
the stacked body includes a first stairs portion processed in a stair-like manner along a third direction that intersects the first direction and the second direction, and a flat portion extending in the third direction from an uppermost surface of the first stairs portion in a flat manner, and
the second pillar structure extends in the first direction in the first stairs portion.

8. The device of claim 7, wherein
the structural body further includes an insulating layer covering an end portion of the first stairs portion, and
the second pillar structure includes a portion extending in the first direction in the insulating layer.

9. The device of claim 1, wherein
the stacked body includes a first stairs portion processed in a stair-like manner along a third direction that intersects the first direction and the second direction, and a flat portion extending in the third direction from an uppermost surface of the first stairs portion in a flat manner,
the structural body further includes an insulating layer covering an end portion of the first stairs portion, and
the plate-shaped structure includes a portion extending in the first direction in the insulating layer.

10. The device of claim 9, wherein
the stacked body further includes a second stairs portion processed in a stair-like manner along the second direction, and
the device further comprises a plurality of contacts each connected to a respective conductive layer of the plurality of conductive layers in the second stairs portion.

11. A semiconductor memory device comprising:
a structural body including a stacked body in which a plurality of conductive layers are stacked to be apart from each other in a first direction;
a plate-shaped structure extending in the first direction and a second direction that intersects the first direction in the structural body to at least a height level corresponding to a height level of a lower surface of the stacked body;
a first pillar structure extending in the first direction in the stacked body and functioning as a NAND string, the first pillar structure having a structure in which a plurality of layers including a first semiconductor layer and extending in the first direction are stacked from an outer peripheral surface side toward an inner side; and
a second pillar structure extending in the first direction in the structural body and not functioning as a NAND string, the second pillar structure having a structure in which a plurality of layers including a second semiconductor layer and extending in the first direction are stacked from an outer peripheral surface side facing the plate-shaped structure toward an inner side,
wherein
materials of the plurality of layers stacked from the outer peripheral surface side toward the inner side in the second pillar structure are respectively same as materials of the plurality of layers stacked from the outer peripheral surface side toward the inner side in the first pillar structure, and
a part of a side surface of the second pillar structure is conformed to a part of a side surface of the plate-shaped structure and includes a flat surface based on the part of the side surface of the plate-shaped structure.

12. The device of claim 11, wherein
the stacked body includes a first stacked portion in which a plurality of first conductive layers of the plurality of conductive layers are stacked in the first direction, and a second stacked portion which is provided on an upper layer side of the first stacked portion and in which a plurality of second conductive layers of the plurality of conductive layers are stacked in the first direction, and
the flat surface is included at least in a region corresponding to a range between a height level corresponding to a height level of an upper surface of the first stacked portion and a height level corresponding to a height level of a lower surface of the first stacked portion.

13. The device of claim 11, wherein
the first pillar structure is apart from the plate-shaped structure.

14. The device of claim 11, wherein
when viewed in the first direction, the second pillar structure has a pattern of such a planar shape that a part of a pattern of a circular or elliptical shape is cut out according to a pattern of the plate-shaped structure.

15. The device of claim 11, wherein
when viewed in the first direction, the plurality of layers stacked from the outer peripheral surface side toward the inner side in the second pillar structure include an innermost layer and other layers surrounding the innermost layer, and each of the other layers has a planar shape that extends continuously along the part of the side surface of the second pillar structure conformed to the part of the side surface of the plate-shaped structure.

16. The device of claim 11, wherein
the stacked body includes a first stairs portion processed in a stair-like manner along a third direction that intersects the first direction and the second direction, and a flat portion extending in the third direction from an uppermost surface of the first stairs portion in a flat manner, and
the second pillar structure extends in the first direction in the flat portion.

17. The device of claim 11, wherein
the stacked body includes a first stairs portion processed in a stair-like manner along a third direction that intersects the first direction and the second direction, and a flat portion extending in the third direction from an uppermost surface of the first stairs portion in a flat manner, and
the second pillar structure extends in the first direction in the first stairs portion.

18. The device of claim 17, wherein
the structural body further includes an insulating layer covering an end portion of the first stairs portion, and
the second pillar structure includes a portion extending in the first direction in the insulating layer.

19. The device of claim 11, wherein
the stacked body includes a first stairs portion processed in a stair-like manner along a third direction that intersects the first direction and the second direction, and a flat portion extending in the third direction from an uppermost surface of the first stairs portion in a flat manner,
the structural body further includes an insulating layer covering an end portion of the first stairs portion, and
the plate-shaped structure includes a portion extending in the first direction in the insulating layer.

20. The device of claim 19, wherein
the stacked body further includes a second stairs portion processed in a stair-like manner along the second direction, and
the device further comprises a plurality of contacts each connected to a respective conductive layer of the plurality of conductive layers in the second stairs portion.
